(19) United States
(12) Patent Application Publication
(10) Pub. No.: US 2026/0305469 A1
(43) Pub. Date: Oct. 1, 2026

(54) PIXEL DEVICE FOR LED DISPLAY AND LED DISPLAY APPARATUS HAVING THE SAME

(71) Applicant: SEOUL VIOSYS CO., LTD., Ansan-si (KR)

(72) Inventors: Namgoo CHA, Ansan-si (KR); Seongchan PARK, Ansan-si (KR); Chung Jae LEE, Ansan-si (KR)

(73) Assignee: SEOUL VIOSYS CO., LTD., Ansan-si (KR)

(21) Appl. No.: 19/636,364

(22) Filed: Apr. 1, 2026

Related U.S. Application Data
(63) Continuation of application No. 17/982,524, filed on Nov. 8, 2022, now Pat. No. 12,616,063.
(60) Provisional application No. 63/277,196, filed on Nov. 9, 2021.

(51) Int. Cl. H10W 90/00; H10H 29/14; H10W 72/00; H10W 72/30; H10W 90/20

(52) U.S. Cl. CPC H10W 90/00; H10H 29/142; H10W 72/07354; H10W 72/347; H10W 72/353; H10W 72/354; H10W 90/297; H10W 90/732

(57) ABSTRACT

A pixel device for an LED display and a display apparatus having the same are provided. A pixel device according to an embodiment includes a first floor including a first LED, and a first lower pad and a first upper pad electrically connected to the first LED; a second floor disposed over the first floor, and including a second LED, and a second lower pad and a second upper pad electrically connected to the second LED; and a third floor disposed over the second floor, and including a third LED, and a third lower pad and a third upper pad electrically connected to the third LED.

### CROSS REFERENCE TO RELATED APPLICATIONS

This application is a continuation application of U.S. application Ser. No. 17/982,524, filed Nov. 8, 2022, which claims priority from provisional application Ser. No. 63/277,196, filed Nov. 9, 2021. The entire contents of the above-identified applications are incorporated herein by reference.

### TECHNICAL FIELD

The present disclosure relates to a pixel device for an LED display that implements an image using a light emitting diode and a display apparatus having the same.

### BACKGROUND ART

Light emitting diodes are inorganic light sources, which are used in various fields such as display apparatuses, automobile lamps, general lighting, and the like. The light emitting diodes have advantages such as longer lifespan, lower power consumption, and quicker response, than conventional light sources, and thus, they have been replacing the conventional light sources.

The conventional light emitting diodes have been generally used as backlight light sources in display apparatuses. However, LED displays that directly realize images using the light emitting diodes have been recently developed.

In general, the display apparatus displays various colors through mixture of blue, green, and red light. In order to realize various images, the display apparatus includes a plurality of pixels, each of the pixels includes sub-pixels of blue, green, and red light, a color of a certain pixel is determined based on colors of the sub-pixels, and images can be realized through a combination of such pixels.

An LED display apparatus implements an image by using a very small LED in a micro unit. To manufacture the LED display apparatus, numerous pixel devices are manufactured, and the pixel devices are mounted on a circuit board using pads formed on the pixel devices. Each of the pixel devices includes one or more pixels. The pixel device may include a pixel in which LEDs are laterally arranged or a pixel in which LEDs are vertically stacked.

The pixel of a vertically stacked structure is generally manufactured by bonding semiconductor layers grown on different growth substrates using a wafer-wafer bonding technique. The pixel device is manufactured by patterning semiconductor layers bonded to one another at a wafer level, forming an electrode structure for electrical connection, and thereafter, dividing the pixel device into individual pixel device units.

According to a prior art, since the electrode structure is formed after bonding the semiconductor layers, etching for different materials such as semiconductor layers and insulation layers is required, and since etching is required through several layers, it is difficult to generate a hole having a relatively large aspect ratio. Accordingly, it is difficult to form the electrode structure, and a pixel manufacturing process is complicated.

Furthermore, since electrical characteristics or optical characteristics can be measured after the pixel device is completed, whether or not the pixel device is defective can be checked only after the pixel device is completed. When a defective pixel device is identified, the defective pixel device is discarded or repaired. Since blue, green, and red LEDs have a stacked structure, even when a defect occurs in any one of the LEDs, it leads to a defect in the pixel device, resulting in a very low yield of the pixel devices. In addition, even when the defective pixel device is repaired, since a repair process has to be performed after a final pixel device is completed, it is relatively difficult to repair the pixel device. Accordingly, even when repair is possible, the defective pixel device is often discarded instead of repairing it due to drawbacks such as process complexity and cost, and thus, it is difficult to increase a process yield of pixel devices through repair.

### DISCLOSURE

### Technical Problem

Exemplary embodiments of the present disclosure provide a pixel device having a structure in which LEDs are vertically stacked and having a novel structure that is configured to increase a process yield, and a display apparatus having the same.

Exemplary embodiments of the present disclosure provide a pixel device that is configured to easily repair defective LEDs during a manufacturing process and a display apparatus having the same.

Exemplary embodiments of the present disclosure may simplify a manufacturing process and provide a pixel device in which an electrode structure is easily formed and a display apparatus having the same.

### Technical Solution

A pixel device according to an exemplary embodiment includes a first floor including a first LED, and a first lower pad and a first upper pad electrically connected to the first LED; a second floor disposed over the first floor, and including a second LED, and a second lower pad and a second upper pad electrically connected to the second LED; and a third floor disposed over the second floor, and including a third LED, and a third lower pad and a third upper pad electrically connected to the third LED.

As used herein, a term “pixel device” refers to a unit device configured to be mounted on a circuit board. The pixel device may include one or more pixels. Meanwhile, the pixel is generally a basic unit constituting an image in a display. To implement a color image, one pixel may include at least three sub-pixels each emitting a single color. Structurally, a term “pixel” refers to a combination of the sub-pixels, and the sub-pixels are stacked one above another.

The first LED, the second LED, and the third LED may emit visible light of different colors from one another. For example, the first LED may emit blue light, the second LED may emit green light, and the third LED may emit red light. In another embodiment, the first LED may emit green light, the second LED may emit blue light, and the third LED may emit red light.

The first through third lower pads may be electrically connected to one another, and the first through third upper pads may be electrically spaced apart from one another.

The pixel device may include a lower adhesive layer bonding the first floor and the second floor; and an upper adhesive layer bonding the second floor and the third floor.

The first through third LEDs may be disposed so as to overlap one another in a vertical direction. A pixel is provided by the first through third LEDs overlapping in the vertical direction.

The first through third LEDs may partially overlap one another.

The pixel device may further include a light blocking layer surrounding the first LED, the second LED, or the third LED.

The first floor may further include a first insulation layer covering the first LEDs and a first planarization layer covering the insulation layer, and the first upper pad may be disposed on the first planarization layer. Furthermore, the first lower pad may be disposed between the first insulation layer and the first planarization layer or on the first planarization layer.

The second floor may further include a second insulation layer covering the second LEDs and a second planarization layer covering the second insulation layer, and the second upper pad may be disposed on the second planarization layer. Furthermore, the second lower pad may be disposed between the second insulation layer and the second planarization layer or on the second planarization layer.

The third floor may further include a third insulation layer covering the third LEDs and a third planarization layer covering the third insulation layer, and the third upper pad may be disposed on the third planarization layer. Furthermore, the third lower pad may be disposed between the third insulation layer and the third planarization layer or on the third planarization layer.

The pixel device may further include an upper insulation layer covering the third floor and pixel device pads disposed on the upper insulation layer. Each of the pixel device pads may be electrically connected to at least one of the first through third lower pads and the first through third upper pads.

A plurality of first LEDs, a plurality of second LEDs, and a plurality of third LEDs may be arranged in a matrix of n×m (n, m is a positive integer) on the first through third floors, respectively, and the number of pixel pad electrodes may be (3 n+m).

The pixel device pads may be electrically connected to at least one of the first through third lower pads and the first through third upper pads through connection vias. The connection vias may be spaced apart from the first through third LEDs in a lateral direction.

The first through third lower pads may be electrically connected to cathodes of the first through third LEDs, respectively, and the first through third upper pads may be electrically connected to anodes of the first through third LEDs, respectively.

A display apparatus according to an embodiment of the present disclosure includes a circuit board and a pixel device disposed on the circuit board, in which the pixel device includes a first floor including a first LED, and a first lower pad and a first upper pad electrically connected to the first LED; a second floor disposed over the first floor, and including a second LED, and a second lower pad and a second upper pad electrically connected to the second LED; and a third floor disposed over the second floor, and including a third LED, and a third lower pad and a third upper pad electrically connected to the third LED.

The pixel device may further include an upper insulation layer disposed on the third floor and pixel device pads disposed on the upper insulation layer, and the pixel device pads may be bonded to the circuit board.

The pixel device pads may be electrically connected to at least one of the first through third lower pads and the first through third upper pads through connection vias, and the connection vias may be spaced apart from the first through third LEDs in a lateral direction.

### DESCRIPTION OF DRAWINGS

FIG. 1A is a schematic plan view illustrating a display apparatus according to an exemplary embodiment.

FIG. 1B are schematic perspective views illustrating various display apparatuses according to an exemplary embodiment.

FIG. 1C is a schematic perspective view illustrating another display apparatus according to an exemplary embodiment.

FIG. 1D is a schematic perspective view illustrating another display apparatus according to an exemplary embodiment.

FIG. 2A is a schematic plan view illustrating a pixel device according to an exemplary embodiment.

FIG. 2B is a schematic cross-sectional view taken along line A-A′ of FIG. 2A.

FIG. 2C is a schematic cross-sectional view taken along line B-B′ of FIG. 2A.

FIG. 3A is a schematic plan view illustrating a first floor of FIG. 2A.

FIG. 3B is a schematic plan view illustrating a second floor of FIG. 2A.

FIG. 3C is a schematic plan view illustrating a third floor of FIG. 2A.

FIGS. 4A, 4B, 5A, 5B, 6A, 6B, 7A, and 7B are schematic cross-sectional views illustrating a manufacturing process of the first floor.

FIGS. 8A, 8B, 9A, 9B, 10A, 10B, 11A, 11B, 12A, 12B, 13A, and 13B are schematic cross-sectional views illustrating a manufacturing process of the second floor.

FIGS. 14A, 14B, 15A, 15B, 16A, 16B, 17A, and 17B are schematic cross-sectional views illustrating a manufacturing process of the third floor.

FIGS. 18A, 18B, 19A, and 19B are schematic cross-sectional views illustrating a process of manufacturing a pixel device by bonding the first through third floors.

FIG. 20 is a schematic cross-sectional view illustrating a pixel module including pixel devices according to an exemplary embodiment.

FIG. 21 is a schematic diagram illustrating a pixel device according to an exemplary embodiment.

FIG. 22A is a schematic plan view illustrating a pixel device according to another exemplary embodiment of the present disclosure.

FIG. 22B is a schematic cross-sectional view taken along line C-C′ of FIG. 22A.

FIG. 22C is a schematic cross-sectional view taken along line D-D′ of FIG. 22A.

FIG. 22D is a schematic cross-sectional view taken along line E-E′ of FIG. 22A.

FIG. 23A is a schematic plan view illustrating a first floor of FIG. 22A.

FIG. 23B is a schematic plan view illustrating a second floor of FIG. 22A.

FIG. 23C is a schematic plan view illustrating a third floor of FIG. 22A.

FIG. 24 is a schematic cross-sectional view illustrating a pixel device according to another exemplary embodiment.

FIG. 25 is a schematic cross-sectional view illustrating a pixel device according to another exemplary embodiment.

### DETAILED DESCRIPTION OF THE ILLUSTRATED EMBODIMENTS

Hereinafter, exemplary embodiments of the present disclosure will be described in detail with reference to the accompanying drawings. The following exemplary embodiments are provided by way of example so as to fully convey the spirit of the present disclosure to those skilled in the art to which the present disclosure pertains. Accordingly, the present disclosure is not limited to the embodiments disclosed herein and can also be implemented in different forms. In the drawings, widths, lengths, thicknesses, and the like of elements can be exaggerated for clarity and descriptive purposes. When an element or layer is referred to as being “disposed above” or “disposed on” another element or layer, it can be directly “disposed above” or “disposed on” the other element or layer or intervening elements or layers can be present. Throughout the specification, like reference numerals denote like elements having the same or similar functions.

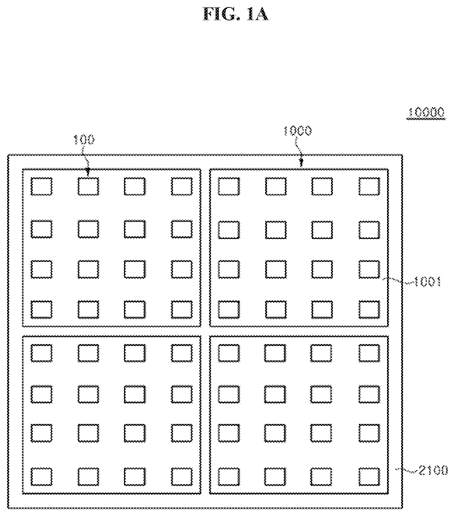

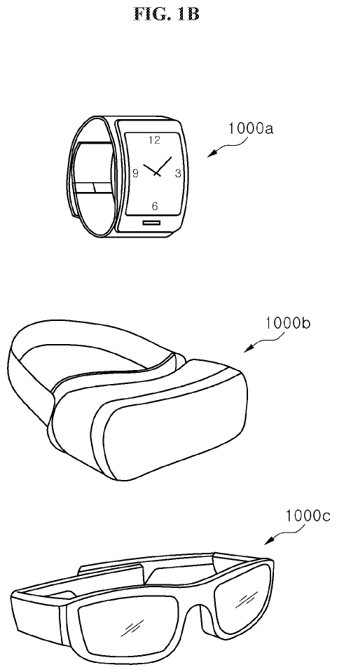

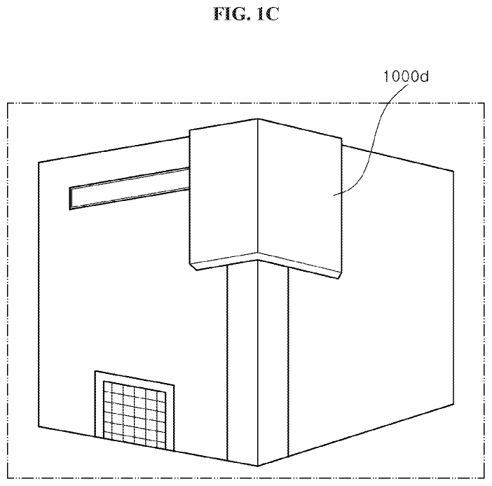

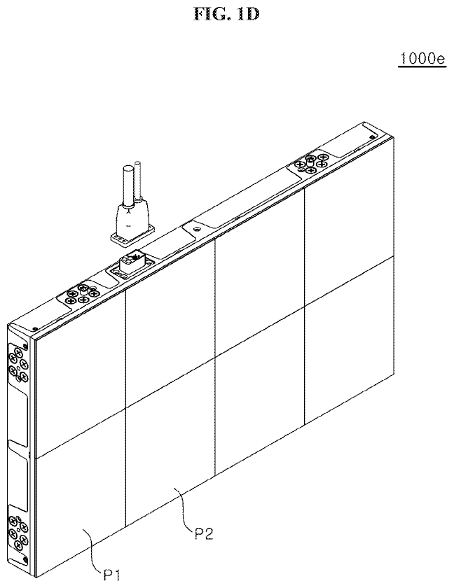

FIG. 1A is a schematic plan view illustrating a display apparatus according to an exemplary embodiment. and FIGS. 1B, 1C, and 1D are schematic perspective views illustrating various display apparatuses 1000a, 1000b, 1000c, and 1000d according to an exemplary embodiment.

Referring to FIG. 1A, a display apparatus 10000 may include a panel substrate 2100 and a plurality of pixel modules 1000.

The display apparatus 10000 is not particularly limited, but may include a smart watch 1000a, a wearable display apparatus 1000b such as a VR headset or glasses, an AR display apparatus 1000c such as augmented reality glasses, or an indoor or outdoor display apparatus 1000d or 1000e such as a micro LED TV or signage. The panel substrate 2100 and the plurality of pixel modules 1000 may be disposed in the display apparatus. A gap between pixels in the display apparatus may be very narrow, for example, the gap between pixels may be 0.01 mm or less. The display apparatus may implement an image through pixels mounted on a circuit board or a transparent substrate. In some display apparatuses, a distance between the display apparatus and an external receiver (e.g., a user's eyes) that recognizes the display may be 200 mm or less. The gap between pixels may be 0.005% to 0.1% of the distance between the external receiver and the display apparatus. The display apparatus may transmit an optical signal from a substrate including a curved surface to the external receiver. The display apparatus may also be a transparent display apparatus using a transparent substrate.

The panel substrate 2100 may include a circuit for a passive matrix driving or active matrix driving manner. In an exemplary embodiment, the panel substrate 2100 may include wirings and resistors therein, and, in another exemplary embodiment, the panel substrate 2100 may include wirings, transistors, and capacitors. The panel substrate 2100 may also have pads that are capable of being electrically connected to the disposed circuit on an upper surface thereof.

In an exemplary embodiment, the plurality of pixel modules 1000 is arranged on the panel substrate 2100. Each of the pixel modules 1000 may include a circuit board 1001, and a plurality of pixel devices 100 disposed on the circuit board 1001, and may include a molding member covering the pixel devices 100. In another exemplary embodiment, the plurality of pixel devices 100 may be directly arranged on the panel substrate 2100, and the molding member may cover the pixel devices 100.

The smart watch 1000a may be 500 to 1500 cd/m² (or nits) or more, and a brightness thereof may be adjusted according to an external illumination. The wearable display apparatus 1000b such as a VR headset or glasses may be 150 to 200 cd/m² (or nits), or a viewing angle thereof may be 50 degrees or more. The indoor or outdoor display apparatus 1000d or 1000e such as Micro LED TV or signage is preferably 1000 cd/m² (or nits) or more, or 80 degrees or more viewing angle, especially for outdoor use, 3000 cd/m² (or nits) or more. In the display apparatus 1000d or 1000e, a plurality of panels P1 and P2 is arranged in rows and columns and attached to a frame, and a plurality of micro LED pixels is disposed on the plurality of panels P1 and P2 to supply electricity or signals, and thus, the display apparatus may be turned on or its luminous intensity may be adjusted according to electricity supply or signals. The plurality of panels P1 and P2 may be connected to an external power source using respective connectors, or the plurality of panels P1 and P2 may be electrically connected to one another using connectors.

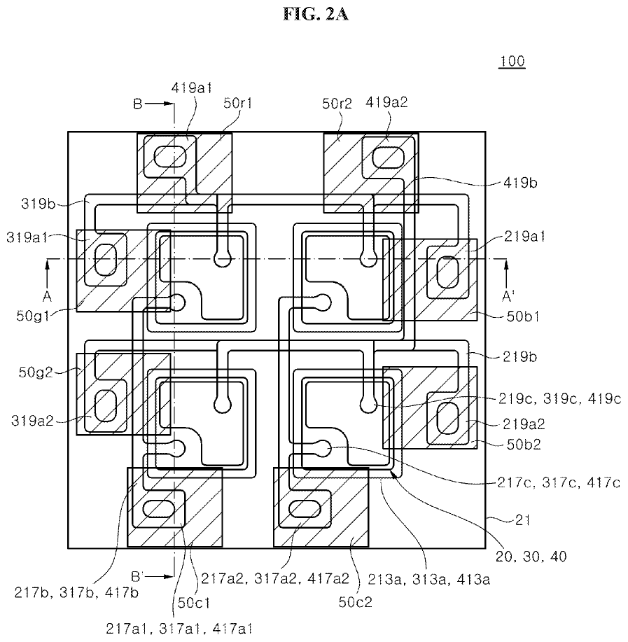

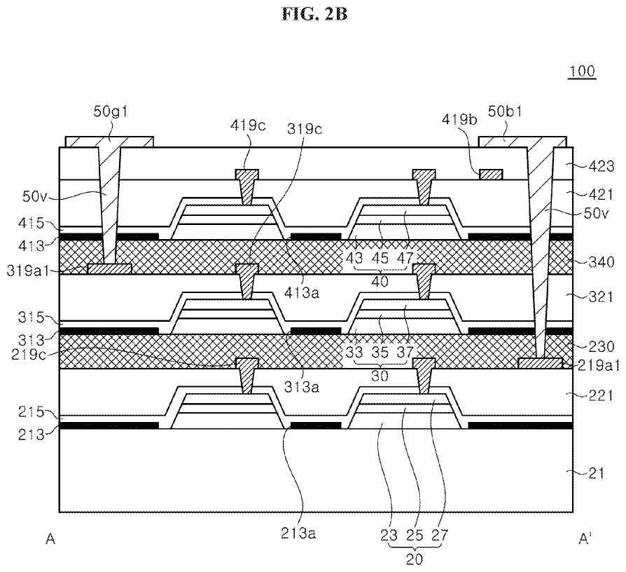

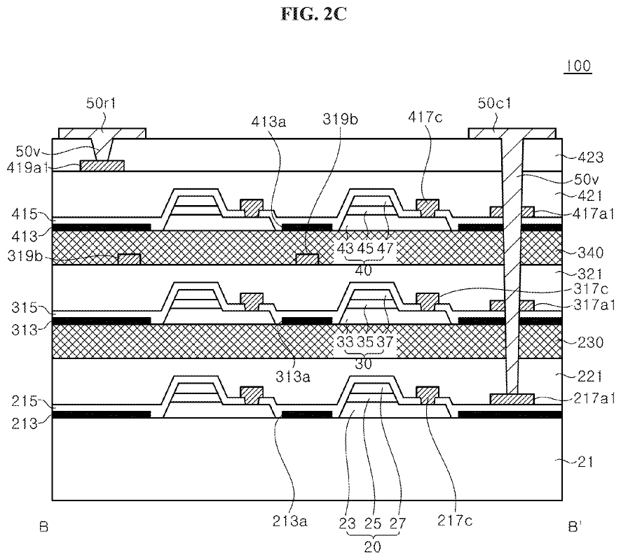

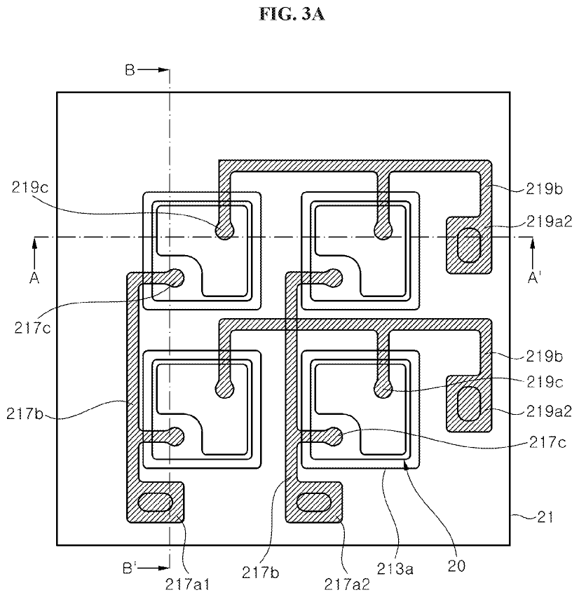

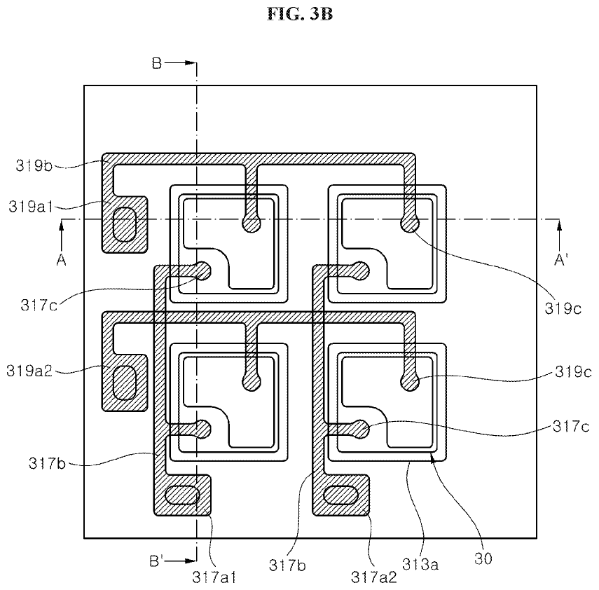

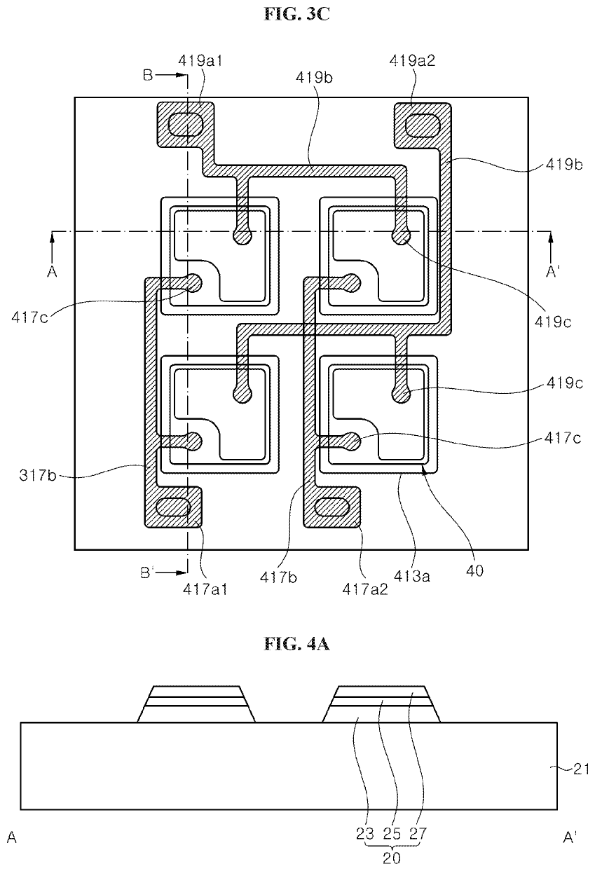

Hereinafter, a pixel device 100 according to an exemplary embodiment will be described in detail with reference to FIGS. 2A, 2B, 2C, 3A, 3B, and 3C.

FIG. 2A is a schematic plan view illustrating the pixel device 100 according to an exemplary embodiment, and FIGS. 2B and 2C are schematic cross-sectional views taken along lines A-A′ and BB′ of FIG. 2A, respectively. The pixel device includes a plurality of floors, and each of the floors is shown in FIGS. 3A, 3B and 3C. Herein, a pixel device including pixels arranged in a 2×2 matrix will be described as an example.

Referring to FIGS. 2A, 2B, and 2C, the pixel device 100 may include a substrate 21, light blocking layers 213, 313, and 413, insulation layers 215, 315, and 415, planarization layers 221, 321 and 421, lower and upper adhesive layers 230 and 340, LEDs 20, 30, and 40, first lower pads 217a1 and 217a2, first lower connection lines 217b, and first lower contacts 217c, first upper pads 219a1 and 219a2, first upper connection lines 219b, first upper contacts 219c, second lower pads 317a1 and 317a2, second lower connection lines 317b, second lower contacts 317c, second upper pads 319a1 and 319a2, second upper connection lines 319b, second upper contacts 319c, third lower pads 417a1 and 417a2, third lower connection lines 417b, third lower contacts 417c, third upper pads 419a1 and 419a2, third upper connection lines 419b, third upper contacts 419c, an upper insulation layer 423, connection vias 50v, and pixel device pads 50r1, 50r2, 50g1, 50g2, 50b1, 50b2, 50c1, and 50c2.

In particular, the pixel device 100 may include first through third floors disposed on the substrate 21, and these floors may be bonded through the adhesive layers 230 and 340, respectively. For example, the first floor includes the LEDs 20, the first lower pads 217a1 and 217a2, the first lower connection lines 217b, the first lower contacts 217c, the first upper pads 219a1 and 219a2, the first upper connection lines 219b, and the first upper contacts 219c, and the second floor includes the LEDs 30, the second lower pads 317a1 and 317a2, the second lower connection lines 317b, the second lower contacts 317c, the second upper pads 319a1 and 319a2, the second upper connection lines 319b, and the second upper contacts 319c, and the third floor includes the LEDs 40, the third lower pads 417a1 and 417a2, the third lower connection lines 417b, the third lower contacts 417c, the third upper pads 419a1 and 419a2, the third upper connection lines 419b, and the third upper contacts 419c.

The substrate 21 is a transparent substrate that transmits light generated in the pixels 20, 30, and 40, and may include a light-transmissive insulating material. In some exemplary embodiments, the substrate 21 may be translucent or partially transparent so as to transmit only light of a specific wavelength or only a portion of light of a specific wavelength. The substrate 21 may include glass, quartz, silicon, an organic polymer, or an organic-inorganic composite material, for example, silicon carbide (SiC), gallium nitride (GaN), indium gallium nitride (InGaN), aluminum gallium nitride (AlGaN), aluminum nitride (AlN), gallium oxide (Ga₂O₃) substrate, and the like. The substrate 21 may be omitted.

### First Floor

Referring to FIGS. 2A, 2B, 2C, and 3A, the LEDs 20 are arranged on the substrate 21. In this embodiment, it is described that four LEDs 20 are arranged, but the inventive concepts are not limited thereto. For example, one LED 20 may be disposed on the substrate 21, or two or more LEDs 20 may be disposed.

Each of the LEDs 20 includes a first conductivity type semiconductor layer 23, an active layer 25, and a second conductivity type semiconductor layer 27. The active layer 25 may be disposed between the first conductivity type semiconductor layer 23 and the second conductivity type semiconductor layer 27. The first conductivity type semiconductor layer 23 may be, for example, an n-type conductivity type semiconductor layer, and the second conductivity type semiconductor layer 27 may be a p-type conductivity type semiconductor layer, and vice versa. In an embodiment, the LED 20 may include a semiconductor material that emits blue light, such as GaN, InGaN, ZnSe, or the like, without being limited thereto, and may emit red or green light.

The LED 20 may be patterned such that a portion of the first conductivity type semiconductor layer 23 is exposed through the second conductivity type semiconductor layer 27 and the active layer 25. As shown in FIG. 2C, a portion of an upper surface of the first conductivity type semiconductor layer 23 is exposed. In this embodiment, it is shown that the second conductivity type semiconductor layer 27 and the active layer 25 are partially removed near an edge of the first conductivity type semiconductor layer 23, but the inventive concepts are not limited thereto, and a through hole passing through the second conductivity type semiconductor layer 27 and the active layer 25 may be formed to expose the first conductivity type semiconductor layer 23.

A light blocking layer 213 is disposed on the substrate 21. The light blocking layer 213 surrounds the LEDs 20 and defines a window region 213a through which light is emitted. The light blocking layer 20 may be formed of, for example, a black matrix, and may improve a contrast ratio by preventing cross-talk between the LEDs 20, 30, and 40 in the display apparatus 10000. The light blocking layer 213 may be omitted.

The window region 213a through which light is emitted to the outside may be larger than or equal to a lower surface area of the LED 20. In an embodiment, the LED 20 may be in contact with the light blocking layer 213.

The insulation layer 215 covers the LEDs 20. Additionally, the insulation layer 215 may cover the light blocking layer 213. The insulation layer 215 may be formed of a light-transmitting material. For example, the insulation layer 215 may include silicon oxide such as SiO₂, silicon nitride such as Si₃N₄, or silicon oxynitride.

The insulation layer 215 may be patterned so as to allow electrical connection to the first conductivity type semiconductor layer 23 and the second conductivity type semiconductor layer 27. For example, the insulation layer 215 may have openings exposing the first conductivity type semiconductor layer 23 and the second conductivity type semiconductor layer 27. A transparent electrode may be formed on the second conductivity type semiconductor layer 27, and in this case, the opening of the insulation layer 215 may expose the transparent electrode.

The first lower pads 217a1 and 217a2, the first lower connection lines 217b, and the first lower contacts 217c are formed on the insulation layer 215. The first lower contacts 217c are electrically connected to the first conductivity type semiconductor layer 23 of the LEDs 20. The first lower contact 217c may be connected to the first conductivity type semiconductor layer 23 through the opening of the insulation layer 215. Since the first lower contacts 217c are disposed on the LEDs 20, respectively, the number of first lower contacts 217c is at least equal to the number of the LEDs 20.

The first lower pads 217a1 and 217a2 may be spaced apart from the LEDs 20 in a lateral direction and disposed on the insulation layer 215. In an embodiment, both of the first lower pads 217a1 and 217a2 are spaced apart from the LEDs 20 and disposed near one side (lower side) of the substrate 21, as shown in FIG. 3A. However, the inventive concepts are not limited thereto, and at least one of the first lower pads 217a1 and 217a2 may be disposed in a region between the LEDs 20. In an embodiment, the first lower pads 217a1 and 217a2 may be disposed at least as many as the number of columns of the LEDs 20. In this embodiment, since the LEDs 20 are disposed in two rows, two first lower pads 217a1 and 217a2 are disposed.

The first lower connection lines 217b connect the first lower contacts 217c to the first lower pads 217a1 and 217a2. As shown in FIG. 3A, the first lower connection lines 217b may electrically connect the first lower contacts 217c on the LEDs 20 disposed in a same column to a same first lower pad 217a1 or 217a2. That is, one first lower connection line 217b connects the first lower contacts 217c disposed in a first column to the first lower pad 217a1, and another first lower connection line 217b connects the first lower contacts 217c disposed in a second column to the first lower pad 217a2. The first lower connection lines 217b may be provided in a same number as those of the first lower pads 217a1 and 217a2.

The planarization layer 221 covers the LEDs 20, the insulation layer 215, the first lower pads 217a1 and 217a2, the first lower contacts 217c, and the first lower connection lines 217b. The planarization layer 221 may cover a surface morphology formed by the LEDs 20 to provide a flat upper surface. The planarization layer 221 may be formed of a light-transmitting insulating material such as polyimide (PI) or epoxy molding compound (EMC).

The first upper pads 219a1 and 219a2, the first upper connection lines 219b, and the first upper contacts 219c are formed on the planarization layer 221. The first upper contacts 219c are electrically connected to the second conductivity type semiconductor layers 27 of the LEDs 20. The first upper contact 219c may be electrically connected to the second conductivity type semiconductor layers 27 through the planarization layer 221 and the insulation layer 215. Since the first upper contacts 219c are disposed on the LEDs 20, respectively, the number of first upper contacts 219c is at least equal to the number of the LEDs 20.

The first upper pads 219a1 and 219a2 may be spaced apart from the LEDs 20 in the lateral direction and disposed on the planarization layer 221. Also, the first upper pads 219a1 and 219a2 are spaced apart from the first lower pads 217a1 and 217a2 in the lateral direction. That is, the first upper pads 219a1 and 219a2 are disposed on the planarization layer 221 so as not to overlap the first lower pads 217a1 and 217a2. In an embodiment, both of the first upper pads 219a1 and 219a2 may be spaced apart from the LEDs 20 and disposed near one side (right side) of the substrate 21, as shown in FIG. 3A. However, the inventive concepts are not limited thereto, and at least one of the first upper pads 219a1 and 219a2 may be disposed in the region between the LEDs 20. In an embodiment, the first upper pads 217a1 and 217a2 may be disposed at least as many as the number of rows of the LEDs 20. In this embodiment, since the LEDs 20 are disposed in two rows, two first upper pads 219a1 and 219a2 are disposed.

The first upper connection lines 219b connect the first upper contacts 219c to the first upper pads 219a1 and 219a2. As shown in FIG. 3A, the first upper connection lines 219b may connect the first upper contacts 219c on the LEDs 20 arranged in a same row to a same first upper pad 219a1 or 219a2. That is, one first upper connection line 219b connects the first upper contacts 219c disposed in a first row to the first upper pad 219a1, and another first upper connection line 219b connects the first upper contacts 219c disposed in a second row to the first upper pad 219a2. The first upper connection lines 219b may be provided in a same number as those of the first upper pads 219a1 and 219a2.

In this embodiment, the first lower pads 217a1 and 217a2 are illustrated and described as being disposed between the insulation layer 215 and the planarization layer 221, but the inventive concepts are not limited thereto. For example, the first lower pads 217a1 and 217a2, the first lower contacts 217c, and the first lower connection lines 217b may be disposed on the planarization layer 221, and the first lower contacts 217c may be electrically connected to the first conductivity type semiconductor layer 23 through the planarization layer 221 and the insulation layer 215. In another embodiment, in addition to the first lower pads 217a1 and 217a2 disposed on the insulation layer 215, additional pads electrically connected to the first lower pads 217a1 and 217a2 may be provided on the planarization layer 221.

### Second Floor

The second floor may include the LEDs 30, the light blocking layer 313, the insulation layer 315, the second lower contacts 317c, the second lower pads 317a1 and 317a2, the second lower connection lines 317b, the planarization layer 321, the second upper contacts 319c, the second upper pads 319a1 and 319a2, and the second upper connection lines 319b. The second floor may be attached to the first floor by the lower adhesive layer 230.

The lower adhesive layer 230 covers the first upper contacts 219c, the first upper pads 219a1 and 219a2, the first upper connection lines 219b, and the planarization layer 221. The lower adhesive layer 230 may include an optically clear adhesive (OCA), which, for example, may include epoxy, polyimide, SU8, spin-on-glass (SOG), benzocyclobutene (BCB), without being limited thereto.

The LEDs 30 may be attached to the lower adhesive layer 230. In this embodiment, it is described that four LEDs 30 are arranged, but the inventive concepts are not limited thereto. The LEDs 30 may be arranged in a same number as that of the LEDs 20, and may be arranged such that at least a portion of a light emitting region overlaps the LEDs 20.

Each of the LEDs 30 includes a first conductivity type semiconductor layer 33, an active layer 35, and a second conductivity type semiconductor layer 37. The active layer 35 may be disposed between the first conductivity type semiconductor layer 33 and the second conductivity type semiconductor layer 37. The first conductivity type semiconductor layer 33 may be, for example, an n-type conductivity type semiconductor layer, and the second conductivity type semiconductor layer 37 may be a p-type conductivity type semiconductor layer, and vice versa. In an embodiment, the LED 30 may include a semiconductor material that emits green light, such as GaN, InGaN, GaP, AlGaInP, AlGaP, or the like, without being limited thereto, and may emit red or blue light.

The LED 30 may be patterned such that a portion of the first conductivity type semiconductor layer 33 is exposed through the second conductivity type semiconductor layer 37 and the active layer 35. As shown in FIG. 2C, a portion of an upper surface of the first conductivity type semiconductor layer 33 is exposed. In this embodiment, it is shown that the second conductivity type semiconductor layer 37 and the active layer 35 are partially removed near an edge of the first conductivity type semiconductor layer 33, but the inventive concepts are not limited thereto, and a through hole passing through the second conductivity type semiconductor layer 37 and the active layer 35 may be formed to expose the first conductivity type semiconductor layer 33.

The light blocking layer 313 is disposed on the lower adhesive layer 230. The light blocking layer 313 surrounds the LEDs 30 and defines a window region 313a through which light is emitted. The light blocking layer 313 may be formed of, for example, a black matrix, and may improve a contrast ratio by preventing cross-talk between the LEDs 20, 30, and 40 in the display apparatus 10000. The light blocking layer 313 may be omitted.

The window region 313a formed by the light blocking layer 313 may be larger than or equal to a lower surface area of the LED 30. In an embodiment, the LED 30 may be in contact with the light blocking layer 313.

The insulation layer 315 covers the LEDs 30. The insulation layer 315 may also cover the light blocking layer 313. The insulation layer 315 may be formed of a light-transmitting material. For example, the insulation layer 315 may include silicon oxide such as SiO₂, silicon nitride such as Si₃N₄, or silicon oxynitride.

The insulation layer 315 may be patterned so as to allow electrical connection to the first conductivity type semiconductor layer 33 and the second conductivity type semiconductor layer 37. For example, the insulation layer 315 may have openings exposing the first conductivity type semiconductor layer 33 and the second conductivity type semiconductor layer 37. A transparent electrode may be formed on the second conductivity type semiconductor layer 37, and in this case, the opening of the insulation layer 315 may expose the transparent electrode.

The second lower pads 317a1 and 317a2, the second lower connection lines 317b, and the second lower contacts 317c are formed on the insulation layer 315. The second lower contacts 317c are electrically connected to the first conductivity type semiconductor layer 33 of the LEDs 30. The second lower contact 317c may be connected to the first conductivity type semiconductor layer 33 through the opening of the insulation layer 315. Since the second lower contacts 317c are disposed on the LEDs 30, respectively, the number of second lower contacts 317c is at least equal to the number of the LEDs 30.

The second lower pads 317a1 and 317a2 may be spaced apart from the LEDs 30 in the lateral direction and disposed on the insulation layer 315. In an embodiment, the second lower pads 317a1 and 317a2 may be disposed so as to overlap the first lower pads 217a1 and 217a2, respectively. For example, both of the second lower pads 317a1 and 317a2 may be spaced apart from the LEDs 30 and disposed near one side (lower side) of the substrate 21, as shown in FIG. 3B. However, the inventive concepts are not limited thereto, and at least one of the second lower pads 317a1 and 317a2 may be disposed in a region between the LEDs 30. Also, the second lower pads 317a1 and 317a2 may be laterally spaced apart from the first lower pads 217a1 and 217a2 so as to partially overlap or so as not to overlap the first lower pads 217a1 and 217a2. In an embodiment, the second lower pads 317a1 and 317a2 may be disposed at least as many as the number of columns of the LEDs 30. In this embodiment, since the LEDs 30 are disposed in two rows, two second lower pads 317a1 and 317a2 are disposed.

The second lower connection lines 317b electrically connect the second lower contacts 317c to the second lower pads 317a1 and 317a2. As shown in FIG. 3A, the second lower connection lines 317b may connect the second lower contacts 317c on the LEDs 30 disposed in a same column to a same second lower pad 317a1 or 317a2. That is, one second lower connection line 317b connects the second lower contacts 317c disposed in a first column to the second lower pad 317a1, and another second lower connection line 317bconnects the second lower contacts 317c disposed in a second column to the second lower pad 317a2. The second lower connection lines 317b may be provided in a same number as those of the second lower pads 317a1 and 317a2.

The planarization layer 321 covers the LEDs 30, the insulation layer 315, the second lower pads 317a1 and 317a2, the second lower contacts 317c, and the second lower connection lines 317b. The planarization layer 321 may cover a surface morphology formed by the LEDs 30 to provide a flat upper surface. The planarization layer 321 may be formed of a light-transmitting insulating material such as polyimide (PI) or epoxy molding compound (EMC).

The second upper pads 319a1 and 319a2, the second upper connection lines 319b, and the second upper contacts 319c are formed on the planarization layer 321. The second upper contacts 319c are electrically connected to the second conductivity type semiconductor layers 37 of the LEDs 30. The second upper contact 319c may be electrically connected to the second conductivity type semiconductor layers 37 through the planarization layer 321 and the insulation layer 315. Since the second upper contacts 319c are disposed on the LEDs 30, respectively, the number of second upper contacts 319c is at least equal to the number of the LEDs 30.

The second upper pads 319a1 and 319a2 may be spaced apart from the LEDs 30 in the lateral direction and disposed on the planarization layer 321. Also, the second upper pads 319a1 and 319a2 are spaced apart from the second lower pads 317a1 and 317a2 in the lateral direction. Furthermore, the second upper pads 319a1 and 319a2 may be spaced apart from the first upper pads 219a1 and 219a2 in the lateral direction. That is, the second upper pads 319a1 and 319a2 may be disposed on the planarization layer 321 so as not to overlap the first lower pads 217a1 and 217a2, the first upper pads 219a1 and 219a2, and the second lower pads 317a1 and 317a2. In an embodiment, both of the second upper pads 319a1 and 319a2 may be spaced apart from the LEDs 30 and disposed near one side (left side) of the substrate 21, as shown in FIG. 3B. However, the inventive concepts are not limited thereto, and at least one of the second upper pads 319a1 and 319a2 may be disposed in the region between the LEDs 30. In an embodiment, the second upper pads 317a1 and 317a2 may be disposed at least as many as the number of rows of the LEDs 30. In this embodiment, since the LEDs 30 are disposed in two rows, two second upper pads 319a1 and 319a2 are disposed.

The second upper connection lines 319b electrically connect the second upper contacts 319c to the second upper pads 319a1 and 319a2. As shown in FIG. 3B, the second upper connection lines 319b may connect the second upper contacts 319c on the LEDs 30 disposed in a same row to a same second upper pad 319a1 or 319a2. That is, one second upper connection line 319b connects the second upper contacts 319c disposed in a first row to the second upper pad 319a1, and another second upper connection line 319b connects the second upper contacts 319c disposed in a second row to the second upper pad 319a2. The second upper connection lines 319b may be provided in a same number as those of the second upper pads 319a1 and 319a2.

In this embodiment, the second lower pads 317a1 and 317a2 are illustrated and described as being disposed between the insulation layer 315 and the planarization layer 321, but the inventive concepts are not limited thereto. For example, the second lower pads 317a1 and 317a2, the second lower contacts 317c, and the second lower connection lines 317b may be disposed on the planarization layer 321, and the second lower contacts 317c may be electrically connected to the first conductivity type semiconductor layer 33 through the planarization layer 321 and the insulation layer 315. In another embodiment, in addition to the second lower pads 317a1 and 317a2 disposed on the insulation layer 315, additional pads electrically connected to the second lower pads 317a1 and 317a2 may be provided on the planarization layer 321.

### Third Floor

The third floor may include the LEDs 40, the light blocking layer 413, the insulation layer 415, the third lower contacts 417c, the third lower pads 417a1 and 417a2, and the third lower connection lines 417b, the planarization layer 421, the third upper contacts 419c, the third upper pads 419a1 and 419a2, and the third upper connection lines 419b. The third floor may be attached to the second floor by the upper adhesive layer 340.

The upper adhesive layer 340 covers the second upper contacts 319c, the second upper pads 319a1 and 319a2, the second upper connection lines 319b, and the planarization layer 321. The upper adhesive layer 340 may include an optically clear adhesive (OCA), for example, epoxy, polyimide, SU8, spin-on-glass (SOG), or benzocyclobutene (BCB), without being limited thereto.

The LEDs 40 may be attached to the upper adhesive layer 340. In this embodiment, it is described that four LEDs 40 are arranged, but the inventive concepts are not limited thereto. The LEDs 30 may be disposed in a same number as that of the LEDs 20 and may be disposed so as to overlap the LEDs 20. One pixel is provided by the LEDs 20, 30, and 40 overlapping one another.

Each of the LEDs 40 includes a first conductivity type semiconductor layer 43, an active layer 45, and a second conductivity type semiconductor layer 47. The active layer 45 may be disposed between the first conductivity type semiconductor layer 43 and the second conductivity type semiconductor layer 47. The first conductivity type semiconductor layer 43 may be, for example, an n-type conductivity type semiconductor layer, and the second conductivity type semiconductor layer 47 may be a p-type conductivity type semiconductor layer, and vice versa. In an embodiment, the LED 40 may include a semiconductor material that emits red light, such as AlGaAs, GaAsP, AlGaInP, and GaP, without being limited thereto, and may emit blue or green light based on a nitride semiconductor.

The LED 40 may be patterned such that a portion of the first conductivity type semiconductor layer 43 is exposed through the second conductivity type semiconductor layer 47 and the active layer 45. As shown in FIG. 2C, a portion of an upper surface of the first conductivity type semiconductor layer 43 is exposed. In this embodiment, it is shown that the second conductivity type semiconductor layer 47 and the active layer 45 are partially removed near an edge of the first conductivity type semiconductor layer 43, but the inventive concepts are not limited thereto, and a through hole passing through the second conductivity type semiconductor layer 47 and the active layer 45 may be formed to expose the first conductivity type semiconductor layer 43.

The light blocking layer 413 is disposed on the upper adhesive layer 340. The light blocking layer 413 surrounds the LEDs 40 and defines a window region 413a through which light is emitted. The light blocking layer 413 may be formed of, for example, a black matrix, and may improve a contrast ratio by preventing cross-talk between the LEDs 20, 30, and 40 in the display apparatus 10000. The light blocking layer 343 may be omitted.

The window region 413a formed by the light blocking layer 413 may be larger than or equal to a lower surface area of the LED 40. In an embodiment, the LED 40 may be in contact with the light blocking layer 413.

The insulation layer 415 covers the LEDs 40. The insulation layer 415 may also cover the light blocking layer 413. The insulation layer 415 may be formed of a light-transmitting material. For example, the insulation layer 415 may include silicon oxide such as SiO₂, silicon nitride such as Si₃N₄, or silicon oxynitride.

The insulation layer 415 may be patterned so as to allow electrical connection to the first conductivity type semiconductor layer 43 and the second conductivity type semiconductor layer 47. For example, the insulation layer 415 may have openings exposing the first conductivity type semiconductor layer 43 and the second conductivity type semiconductor layer 47. A transparent electrode may be formed on the second conductivity type semiconductor layer 47, and in this case, the opening of the insulation layer 415 may expose the transparent electrode.

The third lower pads 417a1 and 417a2, the third lower connection lines 417b, and the third lower contacts 417c are formed on the insulation layer 415. The third lower contacts 417c are electrically connected to the first conductivity type semiconductor layer 43 of the LEDs 40. The third lower contact 417c may be connected to the first conductivity type semiconductor layer 43 through the opening of the insulation layer 415. Since the third lower contacts 417c are disposed on the LEDs 40, respectively, the number of third lower contacts 417c is at least equal to the number of the LEDs 40.

The third lower pads 417a1 and 417a2 may be spaced apart from the LEDs 40 in the lateral direction and disposed on the insulation layer 415. In an embodiment, the third lower pads 417a1 and 417a2 may be disposed so as to overlap the first lower pads 217a1 and 217a2, respectively. For example, all of the third lower pads 417a1 and 417a2 may be spaced apart from the LEDs 40 and disposed near one side (lower side) of the substrate 21, as shown in FIG. 3C. However, the inventive concepts are not limited thereto, and at least one of the third lower pads 417a1 and 417a2 may be disposed in a region between the LEDs 40. In addition, the third lower pads 417a1 and 417a2 may be laterally spaced apart from the first lower pads 217a1 and 217a2 so as to partially overlap or so as not to overlap the first lower pads 217a1 and 217a2. In an embodiment, the third lower pads 417a1 and 417a2 may be disposed at least as many as the number of columns of the LEDs 40. In this embodiment, since the LEDs 40 are disposed in two rows, two second lower pads 417a1 and 417a2 are disposed.

The third lower connection lines 417b electrically connect the third lower contacts 417c to the third lower pads 417a1 and 417a2. As shown in FIG. 3C, the third lower connection lines 417b may connect the third lower contacts 417c on the LEDs 40 disposed in a same column to a same third lower pad 417a1 or 417a2. That is, one third lower connection line 417b connects the third lower contacts 417c disposed in a first column to the third lower pad 417a1, and another third lower connection line 417b connects the third lower contacts 417c disposed in a second column to the third lower pad 417a2. The third lower connection lines 417b may be provided in a same number as that of the third lower pads 417a1 and 417a2.

The planarization layer 421 covers the LEDs 40, the insulation layer 415, the third lower pads 417a1 and 417a2, the third lower contacts 417c, and the third lower connection lines 417b. The planarization layer 421 may cover a surface morphology formed by the LEDs 40 to provide a flat upper surface. The planarization layer 421 may be formed of a light-transmitting insulating material such as polyimide (PI) or epoxy molding compound (EMC).

The third upper pads 419a1 and 419a2, the third upper connection lines 419b, and the third upper contacts 419c are formed on the planarization layer 421. The third upper contacts 419c are electrically connected to the second conductivity type semiconductor layers 47 of the LEDs 40. The third upper contact 419c may be electrically connected to the second conductivity type semiconductor layers 47 through the planarization layer 421 and the insulation layer 415. Since the third upper contacts 419c are disposed on the LEDs 40, respectively, the number of fourth upper contacts 419c is at least equal to the number of the LEDs 40.

The third upper pads 419a1 and 419a2 may be spaced apart from the LEDs 40 in the lateral direction and disposed on the planarization layer 421. However, the inventive concepts are not limited thereto. The third upper pads 419a1 and 419a2 may be disposed so as to overlap the LEDs 40. Also, the third upper pads 419a1 and 419a2 are spaced apart from the third lower pads 417a1 and 417a2 in the lateral direction. Furthermore, the third upper pads 419a1 and 419a2 may be spaced apart from the first upper pads 219a1 and 219a2 and the second upper pads 319a1 and 319a2 in the lateral direction. That is, the third upper pads 419a1 and 419a2 may be disposed on the planarization layer 421 so as not to overlap the first through third lower pads 217a1, 217a2, 317a1, 317a2, 417a1, and 417a2, the first and second upper pads 219a1, 219a2, 319a1, and 319a2. In an embodiment, both of the third upper pads 419a1 and 419a2 may be spaced apart from the LEDs 40 and disposed near one side (upper side) of the substrate 21, as shown in FIG. 3C. However, the inventive concepts are not limited thereto, and at least one of the third upper pads 419a1 and 419a2 may be disposed in the region between the LEDs 40. In an embodiment, the third upper pads 417a1 and 417a2 may be disposed at least as many as the number of rows of the LEDs 40. In this embodiment, since the LEDs 40 are disposed in two rows, two third upper pads 419a1 and 419a2 are disposed.

The third upper connection lines 419b electrically connect the third upper contacts 419c to the third upper pads 419a1 and 419a2. As shown in FIG. 3C, the third upper connection lines 419b may electrically connect the third upper contacts 419c on the LEDs 40 arranged in a same row to a same third upper pad 419a1 or 419a2. That is, one third upper connection line 419b connects the third upper contacts 419c disposed in a first row to the third upper pad 419a1, and another third upper connection line 419b connects the third upper contacts 419c disposed in a second row to the third upper pad 419a2. The third upper connection lines 419b may be provided in a same number as those of the third upper pads 419a1 and 419a2.

In this embodiment, the third lower pads 417a1 and 417a2 are illustrated and described as being disposed between the insulation layer 415 and the planarization layer 421, but the inventive concepts are not limited thereto. For example, the third lower pads 417a1 and 417a2, the third lower contacts 417c, and the third lower connection lines 417b may be disposed on the planarization layer 421, and the third lower contacts 417c may be electrically connected to the first conductivity type semiconductor layer 43 through the planarization layer 421 and the insulation layer 415. In another embodiment, in addition to the third lower pads 417a1 and 417a2 disposed on the insulation layer 415, additional layers electrically connected to the third lower pads 417a1 and 417a2 may be provided on the planarization layer 421.

### Pixel Device Pad

The upper insulation layer 423 and the pixel device pads 50r1, 50r2, 50g1, 50g2, 50b1, 50b2, 50c1, and 50c2 may be disposed on the third floor.

The upper insulation layer 423 may include, for example, an organic material such as polyimide or an epoxy molding compound or an inorganic material such as SiO₂, Si₃N₄, or SiON. Furthermore, the upper insulation layer 423 may include a distributed Bragg reflector. The upper insulation layer 423 covers the planarization layer 421, the third upper contact 419c, the third upper pads 419a1 and 419a2, and the third upper connection lines 419b.

The pixel device pads 50r1, 50r2, 50g1, 50g2, 50b1, 50b2, 50c1, and 50c2 may be disposed on the upper insulation layer 423. The pixel device pads 50r1, 50r2, 50g1, 50g2, 50b1, 50b2, 50c1, and 50c2 may be electrically connected to the first through third lower pads 217a1, 217a2, 317a1, 317a2, 417a1, and 417a2 and the first through third upper pads 219a1, 219a2, 319a1, 319a2, 419a1, and 419a2 through the connection vias 50v.

In this embodiment, the connection vias 50v are laterally or vertically spaced apart from the LEDs 20, 30, and 40. Moreover, the connection vias 50v may be laterally spaced apart from the LEDs 20, 30, and 40 so as not to overlap the LEDs 20, 30, and 40. Accordingly, while the connection vias 50v are formed, electrical connection is possible through a plurality of insulation materials without performing an etching process on LEDs.

The pixel device pads 50r1 and 50r2 may be electrically connected to the third upper pads 419a1 and 419a2 through the connection vias 50v passing through the upper insulation layer 423, respectively. The pixel device pads 50g1 and 50g2 may be electrically connected to the second upper pads 319a1 and 319a2 through the connection vias 50v passing through the upper insulation layer 423, the planarization layer 421, and the upper adhesive layer 340, respectively. In addition, the pixel device pads 50b1 and 50b2 may be electrically connected to the first upper pads 219a1 and 219a2 through the connection vias 50v passing through the upper insulation layer 423, the planarization layer 421, the upper adhesive layer 340, the planarization layer 321, and the lower adhesive layer 230, respectively.

Meanwhile, the pixel device pad 50c1 is commonly electrically connected to the first through third lower pads 217a1, 317a1, and 417a1 through the connection via 50v, and the pixel device pad 50c2 is commonly electrically connected to the third lower pads 217a2, 317a2, and 417a2 through the connection via 50v. As shown in FIG. 2C, when the first lower pad 217a1 or 217a2, the second lower pad 317a1 or 317a2, and the third lower pad 417a1 or 417a2 overlap one another, the connection via 50v may pass through the third lower pad 417a1 or 417a2 and the second lower pad 317a1 or 317a2. In another embodiment, the first lower pad 217a1 or 217a2, the second lower pad 317a1 or 317a2, and the third lower pad 417a1 or 417a2 may be disposed so as not to overlap one another, and the pixel device pad 50c1 or 50c2 may be commonly electrically connected to the first lower pad 217a1 or 217a2, the second lower pad 317a1 or 317a2, and the third lower pad 417a1 or 417a2 through a plurality of connection vias spaced apart from one another.

In this embodiment, it is described that LEDs 20 emit blue light and LEDs 30 emit green light, but they may be interchanged. That is, the LEDs 20 may emit green light, and the LEDs 30 may emit blue light. The pixel device 100 may be flip-bonded to the circuit board 1001 using the pixel device pads 50r1, 50r2, 50g1, 50g2, 50b1, 50b2, 50c1, and 50c2, and light emitted from the LEDs 20, 30, and 40 may be emitted over the circuit board 1001.

In this embodiment, the LEDs 20, 30, and 40 are vertically stacked one above another to constitute a pixel. Each of the LEDs 20, 30, and 40 constitutes a sub-pixel. The LEDs 20, 30, and 40 are disposed on the first through third floors, respectively, and the lower pads 217a1, 217a2; 317a1, 317a2; 417a1, 417a2 and the upper pads 219a1, 219a2; 319a1, 319a2; 419a1, 419a2 connected to the LEDs 20, 30, and 40 are also disposed on corresponding floors. Each of the floors is manufactured through different processes and thereafter, attached to one another using the lower and upper adhesive layers 230 and 340. Accordingly, before bonding the floors, electrical and/or optical characteristics of the LEDs 20, 30, or 40 in each of the floors may be evaluated to select defective LEDs, and repair may be performed for each of the floors. As such, the defective LEDs may be easily repaired, and as a result, a process yield of the pixel device may be improved.

In this embodiment, the pixel device 100 in which four pixels each including vertically stacked LEDs 20, 30, and 40 are arranged has been exemplarily described. When four pixels are arranged, the pixels may be individually driven using at least eight pixel device pads 50r1, 50r2, 50g1, 50g2, 50b1, 50b2, 50c1, and 50c2. Meanwhile, the present disclosure does not specifically limit the number of pixels. For example, the pixel device 100 may include pixels arranged in n rows and m columns of positive integers. In this case, for example, anodes (e.g., second conductivity type semiconductor layers) of the LEDs 20, 30, or 40 disposed on a same floor and in a same row may be commonly connected to a same pixel device pad, respectively, and cathodes (e.g., first conductivity type semiconductor layers) of the LEDs 20, 30, and 40 disposed in a same column may be commonly connected to a same pixel device pad. Since the LEDs 20, 30, and 40 are disposed on three different floors, respectively, the anodes of the LEDs 20, 30, and 40 disposed on the same row are connected to three different pixel device pads, and the cathodes of the LEDs 20, 30, and 40 arranged in the same column are commonly connected to one pixel device pad. Accordingly, pixels arranged in an n×m matrix may be individually driven with only a minimum of (3×n+m) pixel device pads.

In this embodiment, the cathodes of the LEDs 20, 30, and 40 disposed on different floors are described as being commonly electrically connected to one another, and vice versa. That is, cathodes (e.g., first conductivity type semiconductor layers) of the LEDs 20, 30, or 40 disposed on a same floor and in a same row may be commonly connected to a same pixel device pad, respectively, and anodes (e.g., second conductivity type semiconductor layers) of the LEDs 20, 30, and 40 disposed in a same column may be commonly connected to a same pixel device pad.

Hereinafter, a manufacturing method of the pixel device 100 will be described in detail.

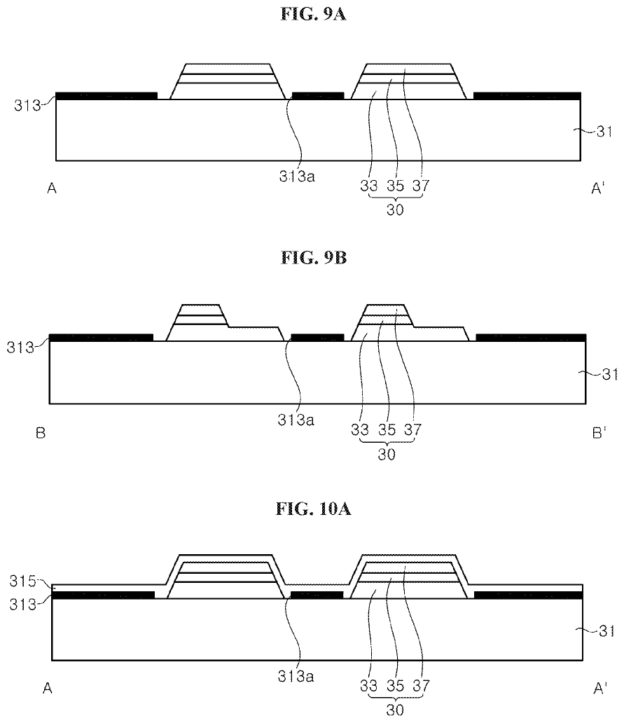

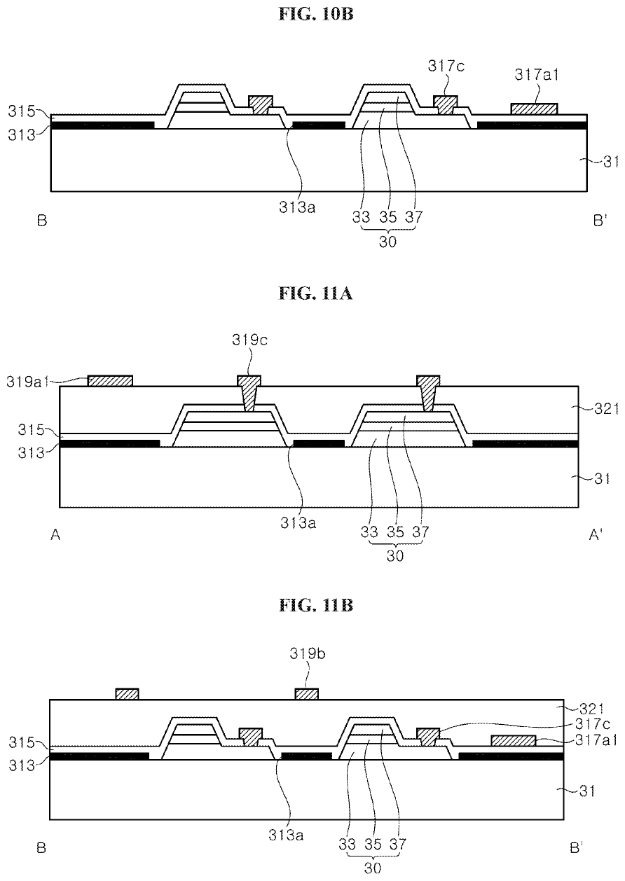

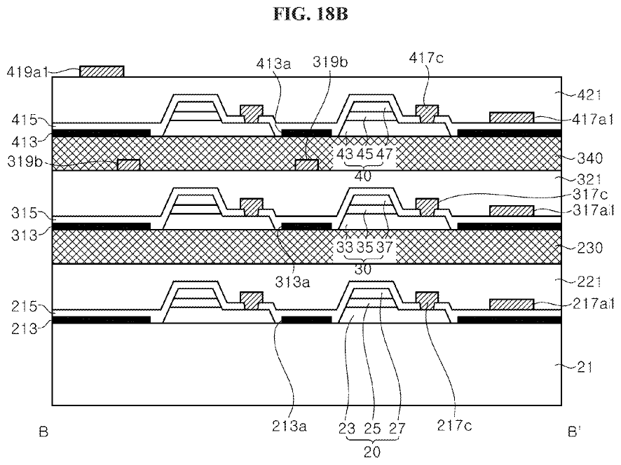

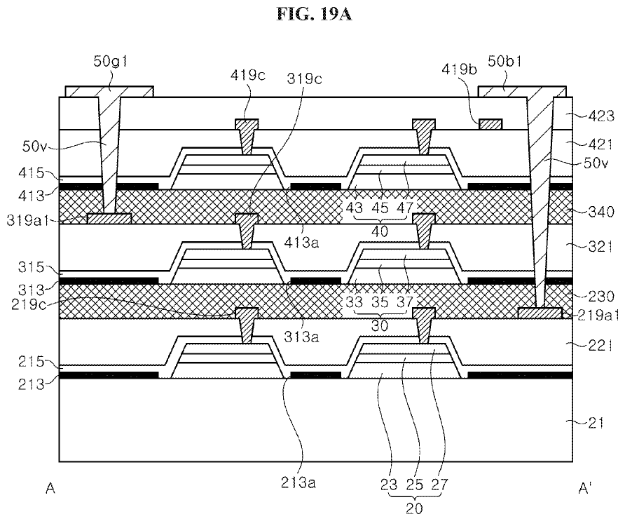

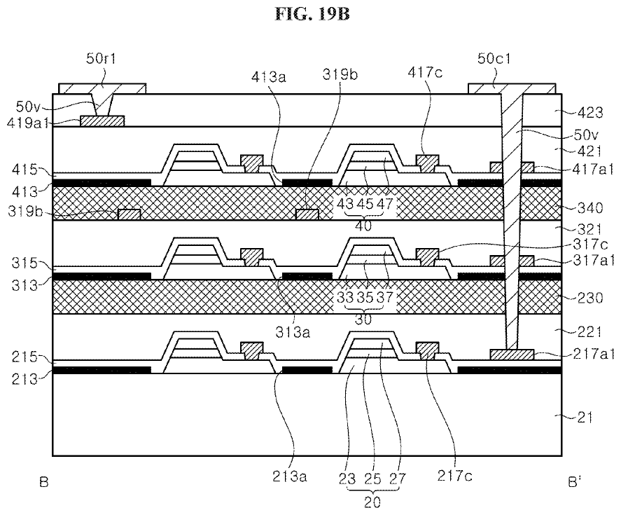

FIGS. 4A, 4B, 5A, 5B, 6A, 6B, 7A, and 7B are schematic cross-sectional views illustrating a manufacturing process of the first floor, and FIGS. 8A, 8B, 9A, 9B 10A, 10B, 11A, 11B, 12A, 12B, 13A, and 13B are schematic cross-sectional views illustrating a manufacturing process of the second floor, FIGS. 14A, 14B, 15A, 15B, 16A, 16B, 17A, and 17B are schematic cross-sectional views illustrating a manufacturing process of the third floor, and FIGS. 18A, 18B, 19A, and 19B are schematic cross-sectional views illustrating a process of manufacturing a pixel device by bonding the first through third floors. Each of the cross-sectional views corresponds to a view taken along line A-A′ or B-B′ in FIGS. 3A, 3B, or 3C.

### Formation of First Floor

First, referring to FIGS. 3A, 4A, and 4B, LEDs 20 are formed on a substrate 21. The substrate 21 is a substrate on which a gallium nitride-based semiconductor layer can be grown, and may be, for example, a sapphire substrate. A first conductivity type semiconductor layer 23, an active layer 25, and a second conductivity type semiconductor layer 27 may be grown on the substrate 21 using, for example, metal organic chemical vapor deposition (MOCVD) technology or molecular beam epitaxy (MBE) technology. The grown semiconductor layers may be patterned using photolithography and etching techniques. The second conductivity type semiconductor layer 27 and the active layer 25 may be partially removed such that a portion of the first conductivity type semiconductor layer 23 is exposed, and the LEDs 20 separated from one another may be formed through an isolation process. Although four LEDs 20 are shown in FIG. 3A, the inventive concepts are not limited thereto. FIG. 3A shows only one block for manufacturing the pixel device 100, and a plurality of blocks may be formed together on the substrate 21.

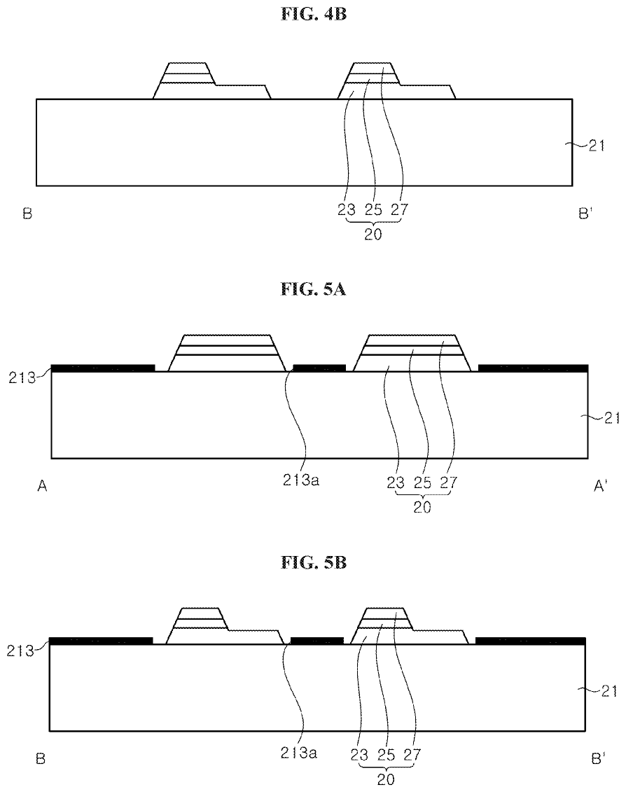

Referring to FIGS. 3A, 5A, and 5B, a light blocking layer 213 may be formed on the substrate 21. The light blocking layer 213 surrounds the LEDs 20 and defines a window region 213a through which light is emitted. The window regions 213a formed by the light blocking layer 213 may be larger than or equal to bottom areas of the corresponding LEDs 20, respectively.

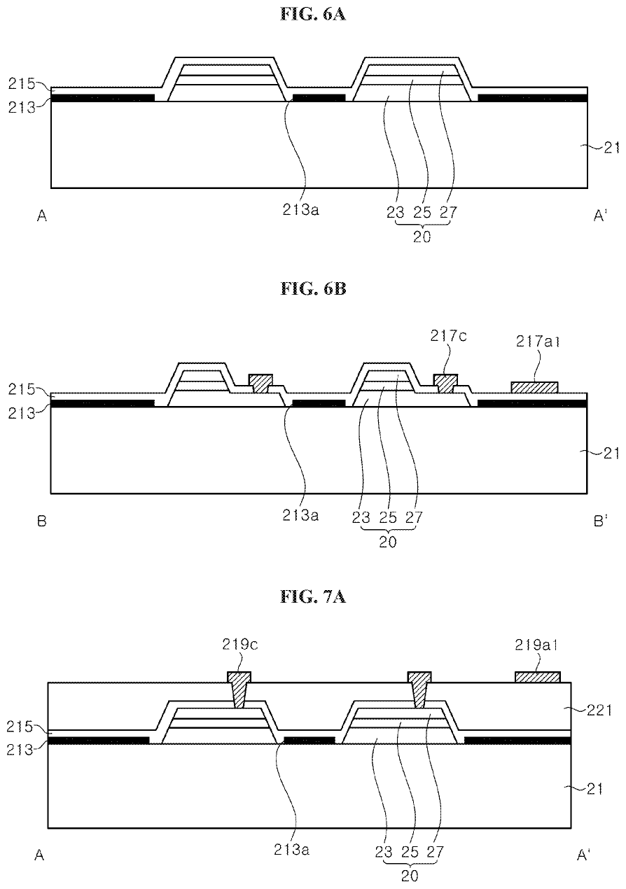

Referring to FIGS. 3A, 6A, and 6B, an insulation layer 215 covering the LEDs 20 is formed. The insulation layer 215 may cover the light blocking layer 213. The insulation layer 215 may be patterned so as to expose the first conductivity type semiconductor layer 23. Although not shown herein, the insulation layer 215 may be patterned so as to expose the first conductivity type semiconductor layer 23 and to expose the second conductivity type semiconductor layer 27. Subsequently, first lower pads 217a1 and 217a2, first lower contacts 217c, and first lower connection lines 217b may be formed. The first lower contacts 217c may be electrically connected to the first conductivity type semiconductor layers 23 through the insulation layer 215.

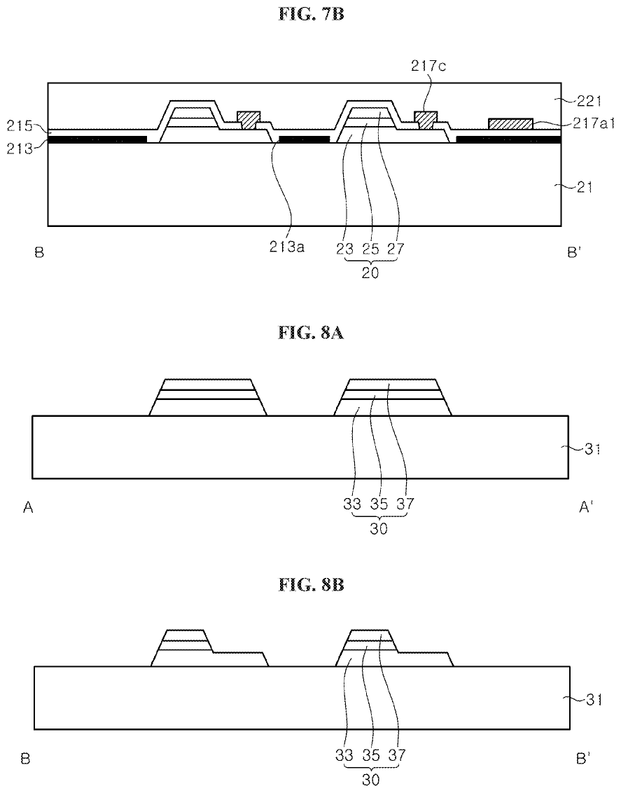

Referring to FIGS. 3A, 7A, and 7B, a planarization layer 221 covering the LEDs 20 is formed. The planarization layer 221 may cover the insulation layer 215, the first lower pads 217a1 and 217a2, the first lower contacts 217c, and the first lower connection lines 217b. The planarization layer 221 may be formed of a transparent insulating material such as polyimide or an epoxy molding compound. The planarization layer 221 covers a surface morphology formed by the LEDs 20 to provide a flat upper surface.

Meanwhile, first upper pads 291a1 and 291a2, first upper contacts 291c, and first upper connection lines 291b may be formed on the planarization layer 221. The second conductivity type semiconductor layer 27 may be partially exposed through the planarization layer 221 and the insulation layer 215, and the first upper contacts 291c may be electrically connected to the second conductivity type semiconductor layers 27 through the planarization layer 221 and the insulation layer 215.

In this embodiment, it is described that the first lower pads 271a1 and 271a2, the first lower contacts 271c, and the first lower connection lines 271c are formed under the planarization layer 221, but the inventive concepts are not limited thereto. For example, the first lower pads 271a1 and 271a2, the first lower contacts 271c, and the first lower connection lines 271c may be formed on the planarization layer 221, and the first lower contacts 271c may be electrically connected to the first conductivity type semiconductor layer 23 through the planarization layer 221 and the insulation layer 215. In another embodiment, additional pads may be formed on the planarization layer 221, and these pads may be electrically connected to the first lower pads 271a1 and 271a2 through connection vias passing through the planarization layer 221.

### Formation of Second Floor

Referring to FIGS. 3B, 8A, and 8B, LEDs 30 are formed on a substrate 31. The substrate 31 is a substrate on which a gallium nitride-based semiconductor layer can be grown, and may be, for example, a sapphire substrate. A first conductivity type semiconductor layer 33, an active layer 35, and a second conductivity type semiconductor layer 37 may be grown on a temporary substrate 31 using, for example, metal organic chemical vapor deposition (MOCVD) technology or molecular beam epitaxy (MBE) technology. The grown semiconductor layers may be patterned using photolithography and etching techniques. The second conductivity type semiconductor layer 37 and the active layer 35 may be partially removed such that a portion of the first conductivity type semiconductor layer 33 is exposed, and the LEDs 30 separated from one another may be formed through an isolation process. The LEDs 30 may be formed in block units so as to correspond to the LEDs 20 formed on the first floor. Although four LEDs 30 are shown in FIG. 3B, the inventive concepts are not limited thereto. FIG. 3B shows only one block for manufacturing the pixel device 100, and a plurality of blocks may be formed together on the substrate 31.

Referring to FIGS. 3B, 9A, and 9B, a light blocking layer 313 may be formed on the substrate 31. The light blocking layer 313 surrounds the LEDs 30 and defines a window region 313a through which light is emitted. The window regions 313a formed by the light blocking layer 313 may be larger than or equal to bottom areas of the corresponding LEDs 30, respectively.

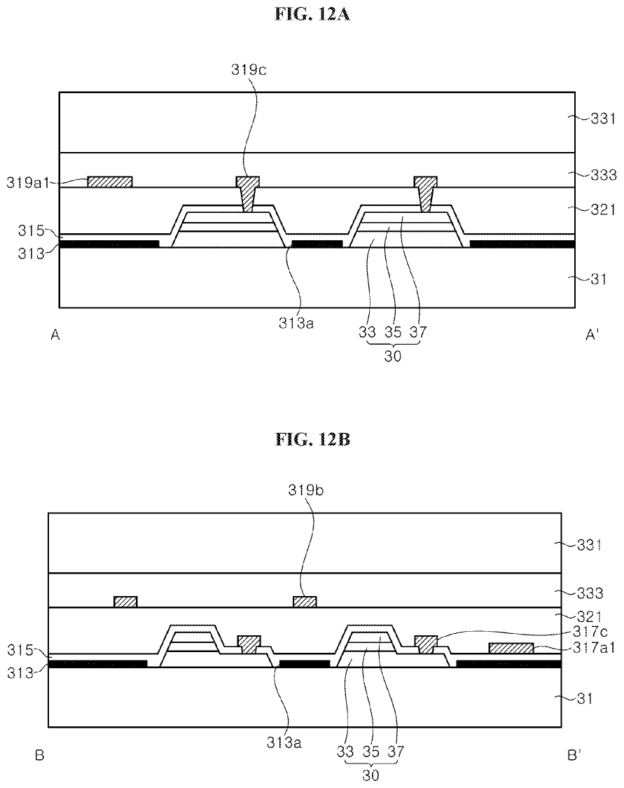

Referring to FIGS. 3B, 10A, and 10B, an insulation layer 315 covering the LEDs 30 is formed. The insulation layer 315 may cover the light blocking layer 313. The insulation layer 315 may be patterned so as to expose the first conductivity type semiconductor layer 33. Although not shown herein, the insulation layer 315 may be patterned so as to expose the first conductivity type semiconductor layer 33 and to expose the second conductivity type semiconductor layer 37. Subsequently, second lower pads 317a1 and 317a2, second lower contacts 317c, and second lower connection lines 317b may be formed. The second lower contacts 317c may be electrically connected to the first conductivity type semiconductor layers 33 through the insulation layer 315.

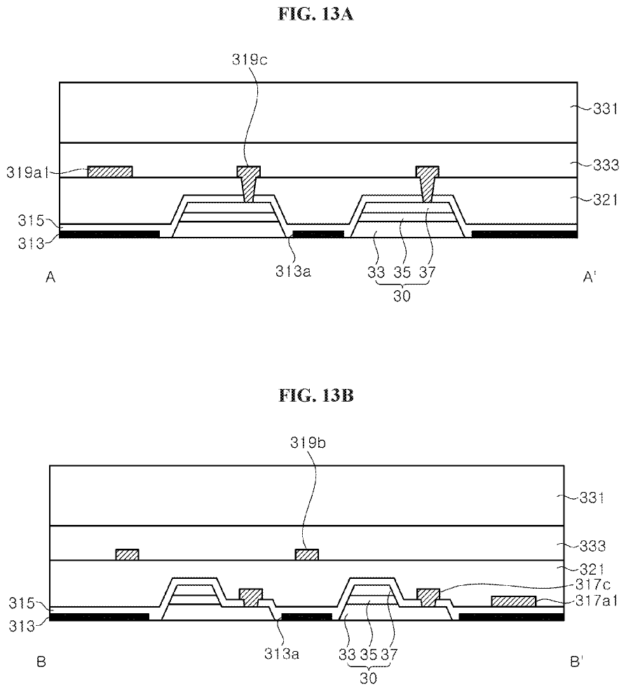

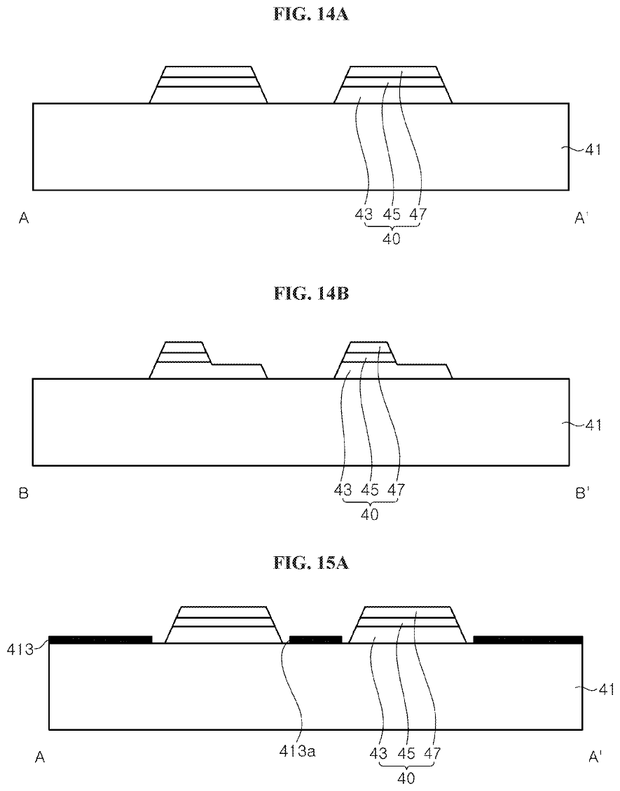

Referring to FIGS. 3B, 11A, and 11B, a planarization layer 321 covering the LEDs 30 is formed. The planarization layer 321 may cover the insulation layer 315, the second lower pads 317a1 and 317a2, the second lower contacts 317c, and the first lower connection lines 317b. The planarization layer 321 may be formed of a transparent insulating material such as polyimide or an epoxy molding compound. The planarization layer 321 covers a surface morphology formed by the LEDs 30 to provide a flat upper surface.

Meanwhile, second upper pads 391a1 and 391a2, second upper contacts 391c, and second upper connection lines 391b may be formed on the planarization layer 321. The second conductivity type semiconductor layer 37 may be partially exposed through the planarization layer 321 and the insulation layer 315, and the second upper contacts 391c may be electrically connected to the second conductivity type semiconductor layers 37 through the planarization layer 321 and the insulation layer 315.

In this embodiment, it is described that the second lower pads 371a1 and 371a2, the second lower contacts 371c, and the second lower connection lines 371c are formed under the planarization layer 321, but the inventive concepts are not limited thereto. For example, the second lower pads 371a1 and 371a2, the second lower contacts 371c, and the second lower connection lines 371c may be formed on the planarization layer 321, and the contacts 371c may be electrically connected to the first conductivity type semiconductor layer 33 through the planarization layer 321 and the insulation layer 315. In another embodiment, additional pads may be formed on the planarization layer 321, and these pads may be electrically connected to the second lower pads 371a1 and 371a2 through connection vias passing through the planarization layer 321.

Referring to FIGS. 3B, 12A, and 12B, a carrier substrate 331 may be attached to the planarization layer 321 using an adhesive tape 333. The carrier substrate 331 is not particularly limited, and may be, for example, a sapphire substrate. The adhesive tape 333 is for attaching the LEDs 30 to the carrier substrate 331, and any tape capable of reducing adhesion by heat or ultraviolet light may be used.

Referring to FIGS. 3B, 13A, and 13B, the substrate 31 from the LEDs 30 may be removed. The substrate 31 may be removed using, for example, a laser lift off technique.

### Formation of Third Floor

Referring to FIGS. 3C, 14A, and 14B, LEDs 40 are formed on a substrate 41. The substrate 41 is a substrate on which a phosphorus nitride (GaP)-based semiconductor layer can be grown, and may be, for example, a GaAs substrate. A first conductivity type semiconductor layer 43, an active layer 45, and a second conductivity type semiconductor layer 47 may be grown on the substrate 41 using, for example, metal organic chemical vapor deposition (MOCVD) technology or molecular beam epitaxy (MBE) technology. The grown semiconductor layers may be patterned using photolithography and etching techniques. The second conductivity type semiconductor layer 47 and the active layer 45 may be partially removed such that a portion of the first conductivity type semiconductor layer 43 is exposed, and the LEDs 40 separated from one another may be formed through an isolation process. The LEDs 40 may be formed in block units so as to correspond to the LEDs 20 formed on the first floor. Although four LEDs 40 are shown in FIG. 3C, the inventive concepts are not limited thereto. FIG. 3C shows only one block for manufacturing the pixel device 100, and a plurality of blocks may be formed together on the substrate 41.

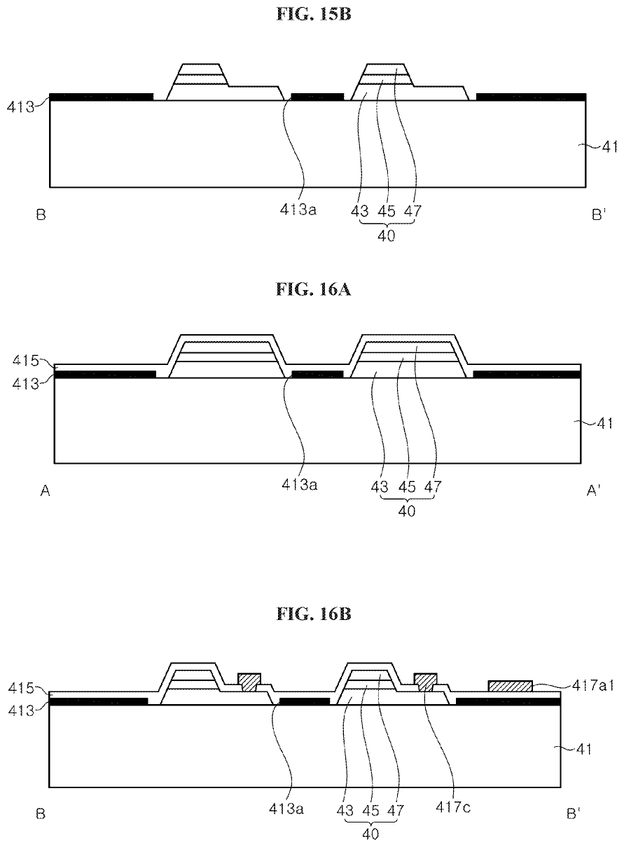

Referring to FIGS. 3B, 15A, and 15B, a light blocking layer 413 may be formed on the substrate 41. The light blocking layer 413 surrounds the LEDs 40 and defines a window region 413a through which light is emitted. The window regions 413a formed by the light blocking layer 413 may be larger than or equal to bottom areas of the corresponding LEDs 40, respectively.

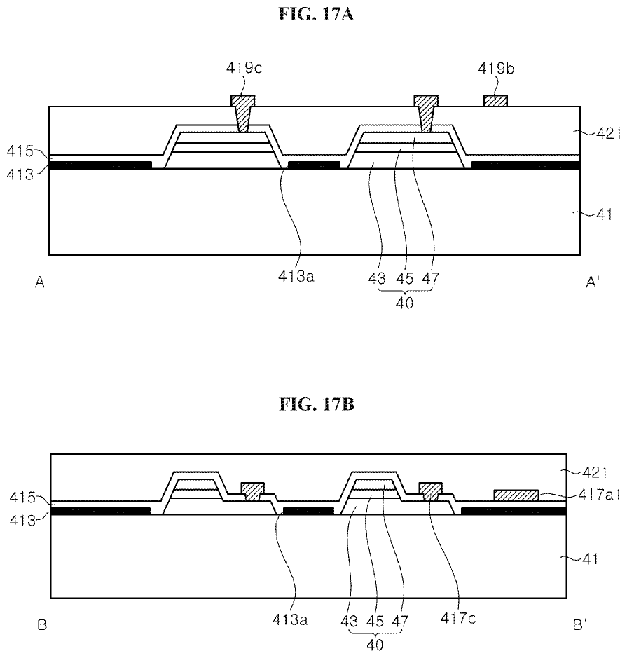

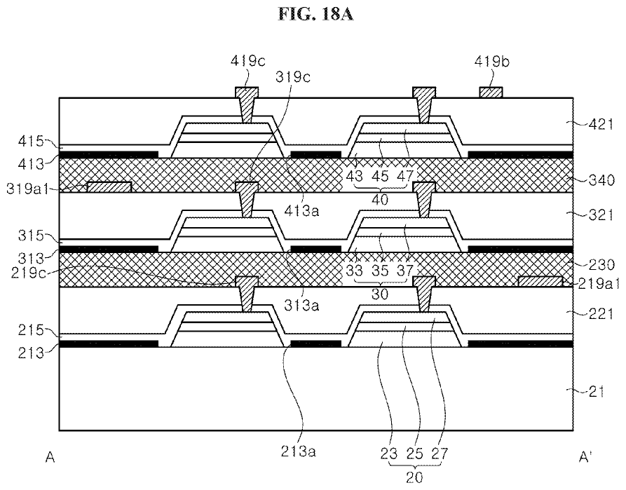

Referring to FIGS. 3C, 16A, and 16B, an insulation layer 415 covering the LEDs 40 is formed. The insulation layer 415 may cover the light blocking layer 413. The insulation layer 415 may be patterned so as to expose the first conductivity type semiconductor layer 43. Although not shown herein, the insulation layer 415 may be patterned so as to expose the first conductivity type semiconductor layer 43 and to expose the second conductivity type semiconductor layer 47. Subsequently, third lower pads 417a1 and 417a2, third lower contacts 417c, and third lower connection lines 417b may be formed. The third lower contacts 417c may be electrically connected to the first conductivity type semiconductor layers 43 through the insulation layer 415, respectively.

Referring to FIGS. 3C, 17A, and 17B, a planarization layer 421 covering the LEDs 40 is formed. The planarization layer 421 may cover the insulation layer 415, the third lower pads 417a1 and 417a2, the third lower contacts 417c, and the first lower connection lines 417b. The planarization layer 421 may be formed of a transparent insulating material such as polyimide or an epoxy molding compound. The planarization layer 421 covers a surface morphology formed by the LEDs 40 to provide a flat upper surface.

Meanwhile, third upper pads 491a1 and 491a2, third upper contacts 491c, and third upper connection lines 491b may be formed on the planarization layer 421. The second conductivity type semiconductor layer 47 may be partially exposed through the planarization layer 421 and the insulation layer 415, and the third upper contacts 491c may be electrically connected to the second conductivity type semiconductor layers 47 through the planarization layer 421 and the insulation layer 415.

In this embodiment, it is described that the third lower pads 471a1 and 471a2, the third lower contacts 471c, and the third lower connection lines 471c are formed under the planarization layer 421, but the inventive concepts are not limited thereto. For example, the third lower pads 471a1 and 471a2, the third lower contacts 471c, and the third lower connection lines 471c may be formed on the planarization layer 421, and the contacts 471c may be electrically connected to the first conductivity type semiconductor layer 43 through the planarization layer 421 and the insulation layer 415. In another embodiment, additional pads may be formed on the planarization layer 421, and these pads may be electrically connected to the third lower pads 471a1 and 471a2 through connection vias passing through the planarization layer 421.

Subsequently, similar to that described with reference to FIGS. 3B, 12A, and 12B, the carrier substrate may be attached to the planarization layer 421 using the adhesive tape, and the substrate 41 may be removed using, for example, a wet etching technique.

### Manufacture of Pixel Device

Referring to FIGS. 2A, 18A, and 18B, the second floor may be attached to the first floor using a lower adhesive layer 230, and the third floor may be attached to the second floor using an upper adhesive layer 340. After attaching the second floor to the first floor, the carrier substrate 331 and the adhesive tape 333 may be removed, and after attaching the third floor to the second floor, the carrier substrate and the adhesive tape may be removed. Accordingly, as shown in FIGS. 18A and 18B, a structure in which the first through third floors are stacked one above another is provided.

Referring to FIGS. 2A, 19A, and 19B, an upper insulation layer 423 may be formed on the third floor. The upper insulation layer 423 may include an organic insulation layer or an inorganic insulation layer. Subsequently, the upper insulation layer 423, the planarization layers 221, 321, and 421, and the lower and upper adhesive layers 230 and 340 may be patterned to form via holes exposing the first through third lower pads 217a1, 271a2, 317a1, 317a2, 417a1, and 417a2 and the first through third upper pads 219a1, 219a2, 319a1, 319a2, 419a1, and 419a2. Thereafter, pixel device pads 50r1, 50r2, 50g1, 50g2, 50b1, 50b2, 50c1, and 50c2 and connection vias 50v may be formed on the upper insulation layer 423 so as to be electrically connected to the first through third lower pads 217a1, 271a2, 317a1, 317a2, 417a1, and 417a2 and the first through third upper pads 219a1, 219a2, 319a1, 319a2, 419a1, and 419a2.

A plurality of blocks may be formed on the substrate 21, and these blocks may be singularized into individual blocks using a cutting technique. Accordingly, a plurality of individually separated pixel devices 100 is provided. The substrate 21 may be removed from the pixel devices 100.

According to this embodiment, the LEDs 20, 30, or 40 are isolated from one another (isolation) on each independently manufactured floor, and the pads electrically connected to the LEDs 20, 30, and 40 are provided. Accordingly, after manufacturing each of the floors, it is possible to electrically and/or optically check whether or not the LEDs 20, 30, and 40 are defective before attaching the floors. Accordingly, since defective LEDs can be repaired in a state in which each of the floors is manufactured, a repair process may be easily performed, and thus, a process yield of the pixel device 100 may be improved.

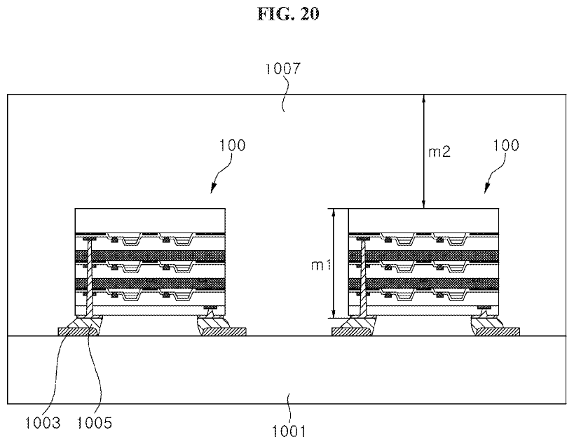

FIG. 20 is a schematic cross-sectional view illustrating a pixel module 1000 including the pixel devices 100 according to an exemplary embodiment.

Referring to FIG. 20, the pixel devices 100 may be flip-bonded to a circuit board 1001 such that the pixel device pads 50r1, 50r2, 50g1, 50g2, 50b1, 50b2, 50c1, and 50c2 are electrically connected to the circuit board 1001. Herein, since the pixel devices 100 are same as those described with reference to FIGS. 2A, 2B, and, a detailed description thereof is omitted to avoid redundancy.

As shown in FIG. 20, the pixel device pads may be bonded to pads 1003 on the circuit board 1001 through a bonding material 1005. A gap between the pads 1003 on the circuit board 1001 may be greater than a gap between the pixel device pads. Meanwhile, the bonding materials 1005 may have a larger gap between lower surfaces than a gap between upper surfaces.

A molding layer 1007 covering a plurality of pixel devices 100 may be formed over the pixel module 1000 in which the plurality of pixel devices 100 is arrayed. The molding layer 1007 is not particularly limited as long as it is a light-transmissive material. A thickness m1 of the pixel device 100 may be smaller than a distance m2 from an upper surface of the molding layer 1007 to an upper surface of the pixel device 100 in contact with the molding layer. Accordingly, the pixel module and the display apparatus can be made thinner, and thus, a distance between the user's eyes and the pixel device 100 may be reduced when viewed from the outside, thereby further improving visibility.

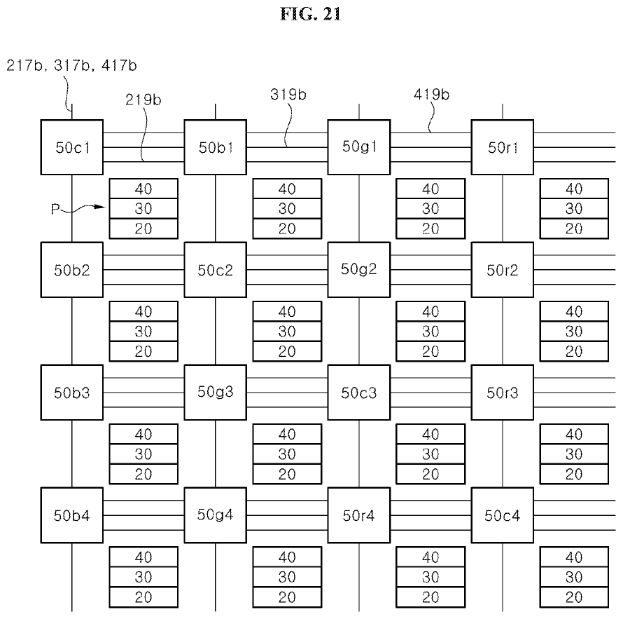

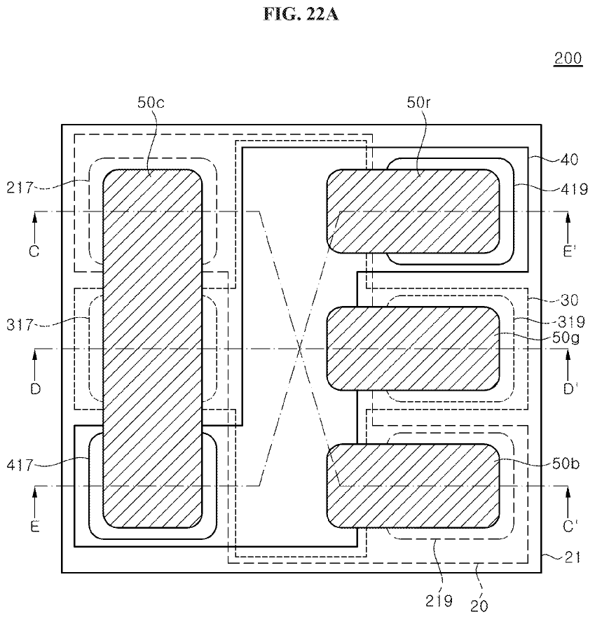

FIG. 21 is a schematic diagram illustrating a pixel device according to an exemplary embodiment.

Although the pixels are described as being arranged in the 2×2 matrix in the above embodiments, the inventive concepts are not limited thereto, and they may be arranged in any matrix. FIG. 21 shows an example in which pixels are arranged in a 4×4 matrix. Each of pixels P includes vertically stacked LEDs 20, 30, and 40. The LEDs 20, 30, and 40 may be electrically connected to first through third lower connection lines 217b, 317b, and 417b and first through third upper connection lines 219b, 319b, and 419b such that the LEDs 20, 30, and 40 can be driven in a passive matrix manner. In the drawings, specific electrical connections of the LEDs 20, 30, and 40 are omitted. For example, the first through third lower connection lines 217b, 317b, and 417b may be commonly electrically connected to cathodes of LEDs arranged in a same column. Since they are commonly electrically connected, the first through third lower connection lines 217b, 317b, and 417b are indicated by a same line in the drawing. The first through third lower connection lines 217b, 317b, and 417b disposed in the same column are electrically connected to a same pixel device pad 50c1, 50c2, 50c3, or 50c4. Accordingly, the pixel device pads 50c1, 50c2, 50c3, and 50c4 may be arranged in corresponding columns. Meanwhile, the LEDs 20, 30, and 40 disposed in a same row are electrically connected to the first through third upper connection lines 219b, 319b, and 419b. As described above, the LEDs 20, 30, or 40 on a same floor are connected to a same upper connection line, but the LEDs disposed on different floors are connected to different upper connection lines. For example, the LEDs 20 disposed on a first floor are connected to the first upper connection line 219b, the LEDs 30 disposed on a second floor are connected to the second upper connection line 319b, and the LEDs 40 disposed on a third floor may be connected to the third upper connection line 419b. Accordingly, the LEDs 20, 30, and 40 disposed in one row are electrically connected to three different upper connection lines 219b, 319b, and 419b. Anodes of the LEDs arranged in four rows are electrically connected to 12 pixel device pads 50r1, 50r2, 50r3, 50r4, 50g1, 50g2, 50g3, 50g4, 50b1, 50b2, 50b3, and 50b4, respectively, and cathodes of the LEDs arranged in four columns are electrically connected to four pixel device pads 50C1, 50C2, 50C3, and 50C4, respectively. Accordingly, a total of 16 pixel device pads may be provided to independently drive the LEDs 20, 30, and 40 in the pixels P.

The pixel device pads 50r1, 50r2, 50r3, 50r4, 50g1, 50g2, 50g3, 50g4, 50b1, 50b2, 50b3, 50b4, 50C1, 50C2, 50C3, and 50C4 may be disposed in various positions. As shown in FIG. 21, in an embodiment, the pixel device pads 50c1, 50b1, 50g1, and 50r1 may be disposed in a first row in this order, the pixel device pads 50b2, 50c2, 50g2, and 50r2 may be disposed in a second row in this order, the pixel device pads 50b3, 50g3, 50c3, and 50r3 may be disposed in a third row, and the pixel device pads 50b4, 50g4, 50r4, and 50c4 may be disposed in a last row. However, an arrangement order of pixel device pads may be changed. The pixel device pads may be arranged in a same shape while maintaining a same distance from one another, but the inventive concepts are not limited thereto.

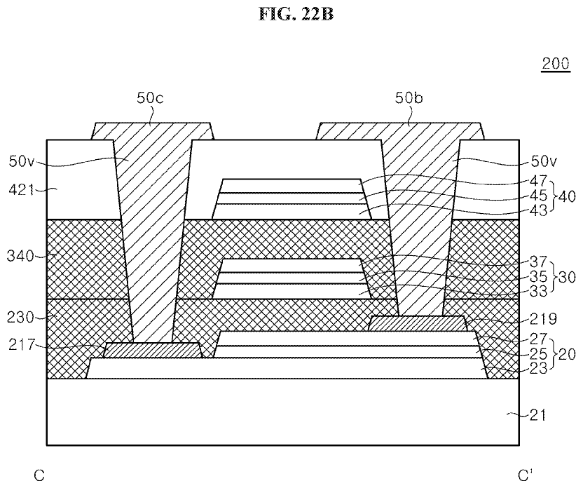

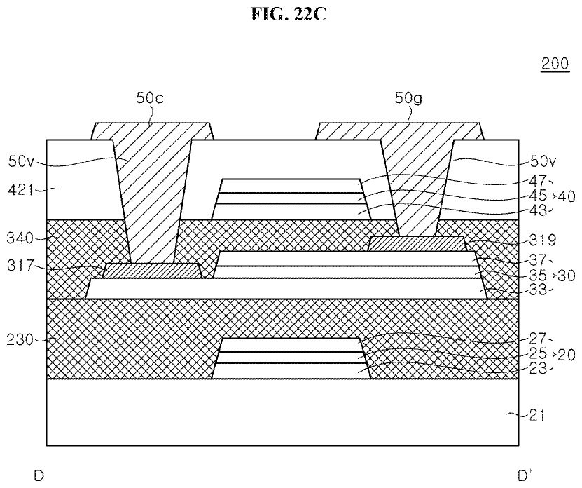

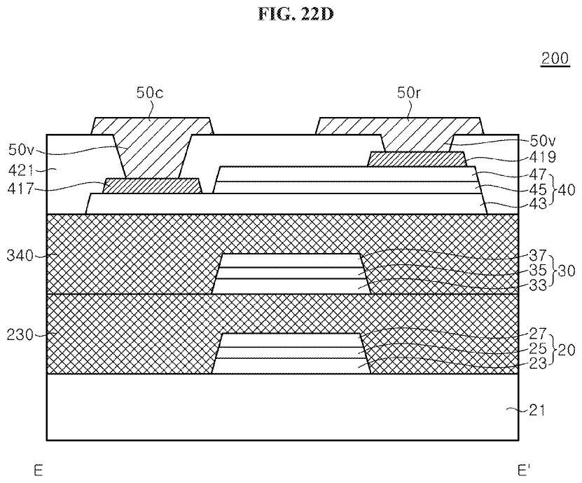

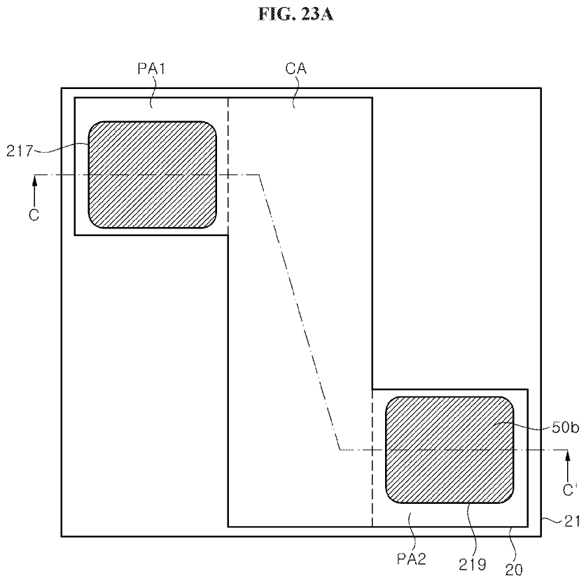

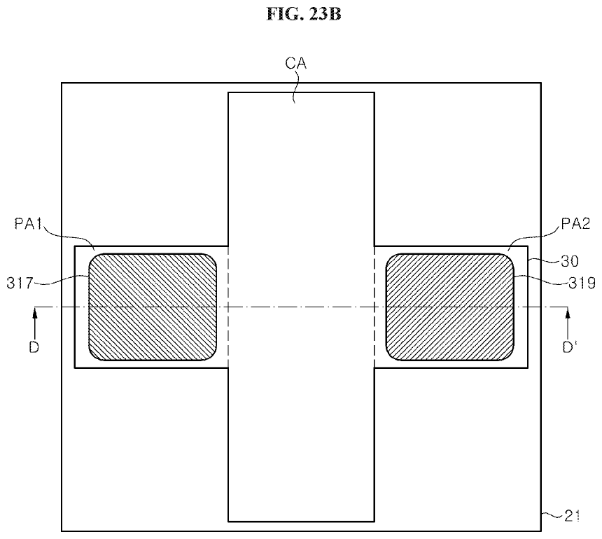

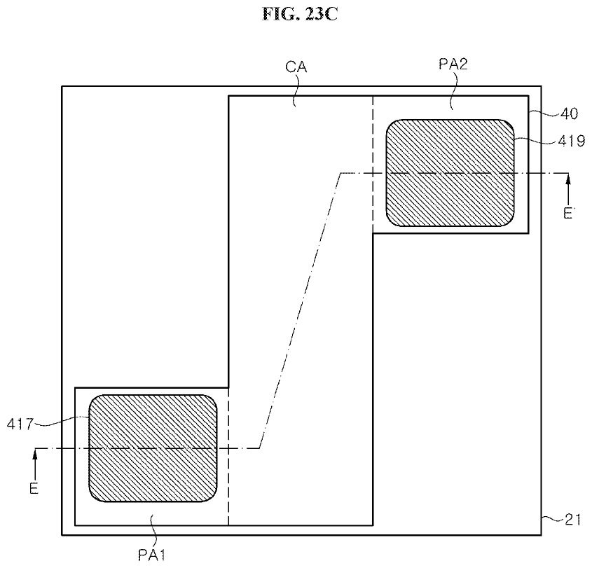

FIG. 22A is a schematic plan view illustrating a pixel device 200 according to another exemplary embodiment of the present disclosure, FIG. 22B is a schematic cross-sectional view taken along line C-C′ of FIG. 22A, FIG. 22C is a schematic cross-sectional view taken along line D-D′ of FIG. 22A, and FIG. 22D is a schematic cross-sectional view taken along line E-E′ of FIG. 22A. Meanwhile, FIGS. 23A through 23C show plan views of LEDs 20, 30, and 40 of first through third floors, respectively.

Referring to FIGS. 22A, 22B, 22C, and 22D, the pixel device 200 according to this embodiment may include a substrate 21, a planarization layer 421, lower and upper adhesive layers 230 and 340, the LEDs 20, 30, and 40, a first lower pad 217, a first upper pad 219, a second lower pad 317, a second upper pad 319, a third lower pad 417, a third upper pad 419, connection vias 50v, and pixel device pads 50r, 50g, 50b, and 50c.

Since the pixel device 200 according to this embodiment is substantially similar to the pixel device 100 described with reference to FIGS. 2A through 2C, same or similar reference numerals are given to same components and detailed descriptions thereof are omitted to avoid redundancy. In particular, the pixel device 200 according to this embodiment, as compared to the pixel device 100 described with reference to FIGS. 2A through 2C, has characteristics that first through third lower pads 217, 317, and 417 and first through third upper pads 219, 319, and 419 are disposed on respective corresponding LEDs 20, 30, and 40, and the LEDs 20, 30, and 40 partially overlap one another.

The pixel device 200 may include the first through third floors disposed on the substrate 21, and these floors may be bonded through the adhesive layers 230 and 340, respectively. For example, as shown in FIG. 23A, the first floor includes the LED 20, the first lower pad 217, and the first upper pad 219, the second floor includes the LED 30, the second lower pad 317, and the second upper pad 319 as shown in FIG. 23B, and the third floor includes the LED 40, the third lower pad 417, and the third upper pad 419. In this embodiment, the pixel device 200 is shown and described as having a single pixel, but may have a plurality of pixels. In this case, a plurality of LEDs is disposed on each of the floors, and the lower pads and the upper pads will be disposed on each of the LEDs.

Since the substrate 21 is same as the substrate 21 described with reference to FIGS. 2A through 2C, a detailed description thereof is omitted to avoid redundancy. The substrate 21 may also be omitted. The pixel device 200 of this embodiment may also include at least one light blocking layer 213, 313, or 413 disposed around the LEDs 20, 30, and 40, as shown in FIGS. 2B and 2C, but they are omitted for convenience of description.

### First Floor

Referring to FIGS. 22A, 22B, 22C and 23A, the LED 20 is disposed on the substrate 21. As described above, the LED 20 includes a first conductivity type semiconductor layer 23, an active layer 25, and a second conductivity type semiconductor layer 27.

The LED 20 may be patterned such that a portion of the first conductivity type semiconductor layer 23 is exposed through the second conductivity type semiconductor layer 27 and the active layer 25. As shown in FIG. 22B, a portion of an upper surface of the first conductivity type semiconductor layer 23 is exposed.

As shown in FIG. 23A, the LED 20 may include a central region CA and peripheral regions PA1 and PA2 extending from the central region. The central region CA may have a vertically elongated rectangular shape, without being limited thereto, and may have various shapes such as a square shape and a circular shape. The peripheral regions PA1 and PA2 may be disposed on both sides with the central region CA interposed therebetween, respectively. The peripheral regions PA1 and PA2 may be disposed symmetrically with each other. For example, the peripheral region PA1 of the LED 20 may extend leftward from one end of the central region CA, and the peripheral region PA2 may extend rightward from the other end of the central region CA. Accordingly, the peripheral regions PA1 and PA2 may be disposed so as to be far apart from each other.

The first conductivity type semiconductor layer 23 may be exposed in the peripheral region PA1. An upper surface of the substrate 21 may be exposed in regions other than the central region CA and the peripheral regions PA1 and PA2.

The first lower pad 217 is disposed on the first conductivity type semiconductor layer 23 exposed in the peripheral region PA1, and the first upper pad 219 is disposed on the second conductivity type semiconductor layer in the peripheral region PA2.

In this embodiment, since the first lower pad 217 and the first upper pad 219 are disposed on the LED 20, the first lower pad 217 and the first upper pad 219 may contact the first and second conductivity type semiconductor layers 23 and 27, respectively. Accordingly, in this embodiment, the lower connection lines are omitted. Furthermore, the first lower pad 217 and the first upper pad 219 may be formed directly on the LED 20, so that the insulation layer 215 and the planarization layer 221 described in the pixel device 100 may be omitted.

### Second Floor

The second floor may include the LED 30, the second lower pads 317, and the second upper pads 319. The second floor may be attached to the first floor by the lower adhesive layer 230. The lower adhesive layer 230 may cover the first lower pad 217, the LED 20, and the first upper pad 219. Further, the lower adhesive layer 230 may contact the substrate 21 exposed around the LED 20.

The LED 30 may be attached to the lower adhesive layer 230. The LED 30 is disposed so as to partially overlap the LED 20. For example, the LED 30 may include a central region CA and peripheral regions PA1 and PA2. The central region CA of the LED 30 may overlap the central region CA of the LED 20, and the peripheral regions PA1 and PA2 of the LED 30 may be disposed on both sides of the central region CA, so as not to overlap the LED 20, respectively. In this embodiment, the peripheral regions PA1 and PA2 of the LED 30 may be symmetrically arranged on left and right sides of the central region CA with respect to the central region CA. Since a material and a layer structure of the LED 30 are same as those described for the pixel device 100, detailed descriptions thereof are omitted.

The LED 30 may be patterned such that a portion of the first conductivity type semiconductor layer 33 is exposed through the second conductivity type semiconductor layer 37 and the active layer 35. As shown in FIG. 22C, a portion of an upper surface of the first conductivity type semiconductor layer 33 is exposed. The first conductivity type semiconductor layer 33 may be exposed in the peripheral region PA1 of the LED 30.

The second lower pad 317 is disposed on the first conductivity type semiconductor layer 33 exposed in the peripheral region PA1, and the second upper pad 319 is disposed on the second conductivity type semiconductor layer 37 in the peripheral region PA2.

In this embodiment, since the second lower pad 317 and the second upper pad 319 are disposed on the LED 30, the second lower pad 317 and the second upper pad 319 may contact the first and second conductivity type semiconductor layers 33 and 37, respectively. Accordingly, in this embodiment, the lower connection lines are omitted. Furthermore, the second lower pad 317 and the second upper pad 319 may be formed directly on the LED 30, so that the insulation layer 315 and the planarization layer 321 described in the pixel device 100 may be omitted.

### Third Floor

The third floor may include the LED 40, the third lower pad 417, and the third upper pad 419. The third floor may be attached to the second floor by the upper adhesive layer 340.

The upper adhesive layer 340 may cover the LED 30, the second lower pad 317, and the second upper pad 319, and may also cover the lower adhesive layer 230.

The LED 40 may be attached to the upper adhesive layer 340. The LED 40 is disposed so as to partially overlap the LED 30. Further, the LED 40 is disposed so as to partially overlap the LED 20. For example, the LED 40 may include a central region CA and peripheral regions PA1 and PA2. The central region CA of the LED 40 may overlap the central regions CA of the LEDs 20 and 30, and the peripheral regions PA1 and PA2 of the LED 40 may be disposed on both sides of the central region CA so as not to overlap either the LED 20 or the LED, respectively. For example, the peripheral regions PA1 and PA2 of the LED 40 may be disposed diagonally on left and right sides of the central region CA with respect to the central region CA. For example, the peripheral region PA2 may extend rightward from one end of the central region CA, and the peripheral region PA1 may extend leftward from the other end of the central region CA. Since a material and a layer structure of the LED 40 are same as those described for the pixel device 100, detailed descriptions thereof are omitted.

The LED 40 may be patterned such that a portion of the first conductivity type semiconductor layer 43 is exposed through the second conductivity type semiconductor layer 47 and the active layer 45. As shown in FIG. 22D, a portion of an upper surface of the first conductivity type semiconductor layer 43 is exposed. The first conductivity type semiconductor layer 43 may be exposed in the peripheral region PA1 of the LED 40.

The third lower pad 417 is disposed on the first conductivity type semiconductor layer 43 exposed in the peripheral region PA1, and the third upper pad 419 is disposed on the second conductivity type semiconductor layer in the peripheral region PA2.

In this embodiment, since the third lower pad 417 and the third upper pad 419 are disposed on the LED 40, the third lower pad 417 and the third upper pad 419 may contact the first and second conductivity type semiconductor layers 43 and 47, respectively. Accordingly, in this embodiment, the lower connection lines are omitted. Furthermore, the third lower pad 417 and the third upper pad 419 may be formed directly on the LED 40, so that the insulation layer 415 described in the pixel device 100 may be omitted.

The planarization layer 421 covers the LED 40, the third lower pad 417, and the third upper pad 419. The planarization layer 421 may cover a surface morphology formed by the LEDs 40 to provide a flat upper surface. The planarization layer 421 may be formed of a light-transmitting insulating material such as polyimide (PI) or epoxy molding compound (EMC).

### Pixel Device Pad

The pixel device pads 50r, 50g, 50b, and 50c may be disposed on the third floor. In this embodiment, since the third upper pad 419 is disposed under the planarization layer 421, the upper insulation layer 423 of the pixel device 100 may be omitted.

The pixel device pads 50r, 50g, 50b, and 50c may be disposed on the planarization layer 421. The pixel device pads 50r, 50g, 50b, and 50c may be electrically connected to the first through third lower pads 217, 317, and 417 and the first through third upper pads 219, 319, and 419 through the connection vias 50v.

In this embodiment, the connection vias 50v are disposed on corresponding LEDs among the LEDs 20, 30, and 40, and may be laterally spaced apart from the other LEDs. The connection vias 50v do not pass through the LEDs 20, 30, and 40, and thus, there is no need to perform an etching process on the LEDs while the connection vias 50v are formed.

The pixel device pad 50r may be electrically connected to the third upper pad 419 through the connection via 50v passing through the planarization layer 421. The pixel device pad 50g may be electrically connected to the second upper pads 319 through the connection via 50v passing through the planarization layer 421 and the upper adhesive layer 340. In addition, the pixel device pad 50b may be electrically connected to the first upper pad 219 through the connection via 50v passing through the planarization layer 421, the upper adhesive layer 340, and the lower adhesive layer 230.

Meanwhile, the pixel device pad 50c may be commonly electrically connected to the first through third lower pads 217, 317, and 417 through the connection via 50v. As shown in FIG. 22A, since the first lower pad 217, the second lower pad 317, and the third lower pad 417 are disposed so as not to overlap one another, the pixel device pads 50c may be commonly electrically connected to the first lower pad 217, the second lower pad 317, and the third lower pad 417 through a plurality of connection vias 50v spaced apart from one another.

In this embodiment, the LED 20 may emit blue light, the LED 30 may emit green light, and the LED 40 may emit red light. In another embodiment, the LED 20 may emit green light, the LED 30 emit blue light, and the LED 40 emit red light. The pixel device 200 may be flip-bonded to a circuit board 1001 using the pixel device pads 50r, 50g, 50b, and 50c, and light generated from the LEDs 20, 30, and 40 may be emitted over the circuit board 1001.

In this embodiment, the LEDs 20, 30, and 40 are partially vertically stacked one above another to constitute pixels. Each of the LEDs 20, 30, and 40 constitutes a sub-pixel. The LEDs 20, 30, and 40 are disposed on the first through third floors, respectively, and the lower pads 217, 317, and 417 and the upper pads 219, 318, and 419 connected to the LEDs 20, 30, and 40 are also disposed on corresponding floors. Since the pixel device 200 according to this embodiment may be manufactured in a substantially similar manner to that described in the manufacturing method of the pixel device 100, a detailed description thereof will be omitted to avoid redundancy. In particular, each of the floors is manufactured through different processes and then attached to one another using the lower and upper adhesive layers 230 and 340. Accordingly, before bonding the floors, electrical and/or optical characteristics of the LEDs 20, 30, or 40 in each of the floors may be evaluated to select defective LEDs, and repair may be performed for each of the floors. As such, the defective LEDs may be easily repaired, and as a result, a process yield of the pixel device may be improved.

In this embodiment, the cathodes of the LEDs 20, 30, and 40 disposed on different floors are described as being commonly electrically connected to one another, and vice versa.

In this embodiment, a width of a region where the lower pads 217, 317, and 417 are disposed may be formed smaller than that of a light emitting region where the plurality of LEDs overlaps. Alternatively, at least one LED may have a groove such that the lower pads 217, 317, and 417 are disposed in a region protruding outward from the light emitting region. Alternatively, in plan view, each of the lower pads 217, 317, and 417 may be disposed spaced apart so as not to overlap one another, and may be disposed in a groove region of an LED not electrically connected with thereof.

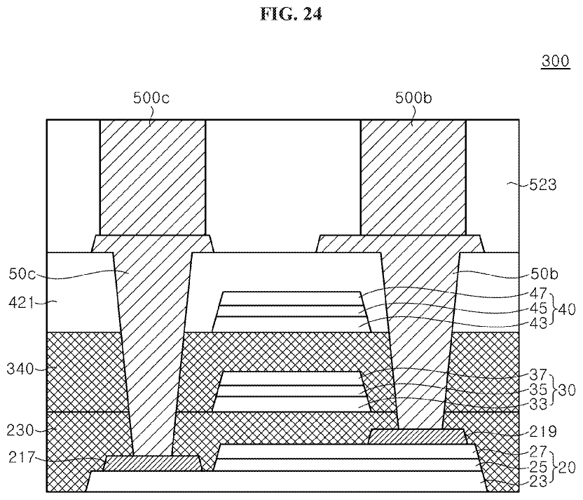

FIG. 24 is a schematic cross-sectional view illustrating a pixel device 300 according to another exemplary embodiment of the present disclosure.

Referring to FIG. 24, the pixel device 300 according to this embodiment is substantially similar to the pixel device 200 described with reference to FIGS. 22A through 22D, except that it includes metal pads 500b and 500c and an upper insulating material layer 523.

The upper insulating material layer 523 may be thicker than the planarization layer 421. The upper insulating material layer 523 may be formed of polyimide or an epoxy molding compound. The upper insulating material layer 523 may have openings exposing the pixel device pads 50r, 50g, 50g, and 50c, and the metal pads 500b and 500c may fill the openings in the upper insulating material layer 523. Although FIG. 24 shows two metal pads 500b and 500c formed on the pixel device pads 50b and 50c, the metal pads may also be disposed on the pixel device pads 50r and 50g. The metal pads may be electrically connected to corresponding pixel device pads 50r, 50g, 50b, and 50c. In this embodiment, for convenience of description, it is referred to as the pixel device pads 50r, 50g, 50b, and 50c and the metal pads 500b and 500c, but the metal pads 500b and 500c may function as final pixel device pads of the pixel device 300, and the pixel device pads 50r, 50g, 50g, and 50c may function as intermediate connection pads. The pixel device 300 may be mounted on the circuit board 1001 using the metal pads.

In this embodiment, the substrate 21 previously described may be omitted. The substrate 21 may be separated from the first floor using, for example, a laser lift-off technique or the like. Accordingly, the first floor may be exposed to the outside.

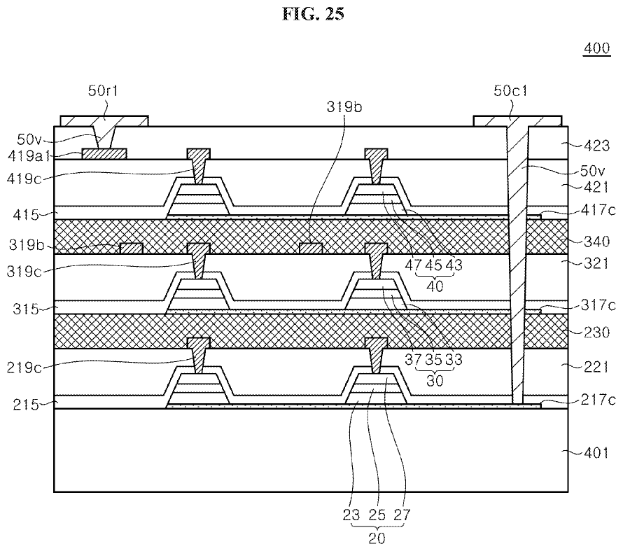

FIG. 25 is a schematic cross-sectional view illustrating a pixel device 400 according to another exemplary embodiment of the present disclosure.

Referring to FIG. 25, since the pixel device 400 according to this embodiment is substantially similar to the pixel device 100 described with reference to FIGS. 2A through 2C, same or similar reference numerals are given to same components and detailed descriptions thereof are omitted to avoid redundancy.

Compared to the pixel device 100 described with reference to FIGS. 2A through 2C, in the pixel device 400 according to this embodiment, the first through third lower contact layers 217c, 317c, and 417c are disposed on corresponding LEDs 20, 30, and 40, respectively, instead of the first through third lower contacts, the first through third lower connection lines, and the first through third lower pads of FIGS. 2A through 2C. As shown in FIG. 25, the first through third lower contact layers 217c, 317c, and 417c are disposed on light exiting surfaces of corresponding LEDs 20, 30, and 40, respectively. The first through third lower contact layers 217c, 317c, and 417c may be disposed so as to face the first through third upper contacts 219c, 319c, and 419c with the corresponding LEDs 20, 30, and 40 interposed therebetween. Accordingly, electric flow is generated vertically inside of each of the LEDs 20, 30, and 40, thereby improving luminous efficiency.

The pixel device 400 may include first through third floors disposed on a substrate 401, and these floors may be bonded through the adhesive layers 230 and 340, respectively. As shown in FIG. 25, the first lower contact layer 217c is disposed between the substrate 401 and the LEDs 20, the second lower contact layer 317c is disposed between the lower adhesive layer 230 and the LEDs 30, and the third lower contact layer 417c is disposed between the upper adhesive layer 340 and the LEDs 40. A plurality of LEDs may be disposed on each of the first through third floors, and the first through third lower contact layers 217c, 317c, and 417c may electrically connect adjacent LEDs. Furthermore, the first through third lower contact layers 217c, 317c, and 417c may extend to the outside of the LEDs 20, 30, and 40, respectively, and serve as pads to which the vias 50v are connected.

In this embodiment, the substrate 401 may be a substrate attached to the LED 20, unlike a growth substrate of the LED 20, and may be omitted.

### First Floor

Referring to FIG. 25, the LED 20 is disposed on the substrate 401. As described above, the LED 20 includes the first conductivity type semiconductor layer 23, the active layer 25, and the second conductivity type semiconductor layer 27.

The first conductivity type semiconductor layer 23 of the LED 20 may include a first surface facing the active layer 25 and a second surface opposite the first surface, and a growth substrate is removed to expose the second surface of the first conductivity type semiconductor layer 23.

The first lower contact layer 217c is disposed on the exposed second surface of the first conductivity type semiconductor layer 23, and the first upper contact layer 219c is disposed on the second conductivity type semiconductor layer. The first lower contact layer 217c may extend to the outside of the LED 20 and electrically connected to the pixel device pad 50c1 through the via 50v. The first lower contact layer 217c may electrically connect adjacent LEDs 20, and furthermore, a plurality of first lower contact layers 217c may be disposed. The first lower contact layers 217c may be electrically connected to different pixel device pads (e.g., 50c1 and 50c2 of FIG. 2A).

The first lower contact layer 217c includes a region overlapping the LED 20, and may additionally extend to the outside of the LED 20. The first lower contact layer 217c may be formed of a light-transmitting material such as a metallic material or a conductive oxide layer. In particular, the first lower contact layer 217c may be formed of a material that is transparent to light emitted from the LEDs 20, 30, and 40.

### Second Floor

The second floor may be attached to the first floor by the lower adhesive layer 230. The LEDs 30 may be arranged on the lower adhesive layer 230. The second lower contact layer 317c is disposed between the lower adhesive layer 230 and the LEDs 30. The LEDs 30 are disposed so as to at least partially overlap the LEDs 20, respectively.

The first conductivity type semiconductor layer 33 of the LED 30 may include a first surface facing the active layer 35 and a second surface opposite to the first surface, and a growth substrate is removed to expose the first conductivity type semiconductor layer 33.

The second lower contact layer 317c is disposed on the exposed second surface of the first conductivity type semiconductor layer 33, and the second upper contact layer 319c is disposed on the second conductivity type semiconductor layer. The second lower contact layer 317c and the second upper contact 319c may be electrically connected to the first and second conductivity type semiconductor layers 33 and 37, respectively.

The second lower contact layer 317c may extend to the outside of the LED 30, and electrically connected to the pixel device pad 50c1 through the via 50v. The second lower contact layer 317c may electrically connect adjacent LEDs 30, and furthermore, a plurality of second lower contact layers 317c may be disposed. The second lower contact layers 317c may be electrically connected to different pixel device pads (e.g., 50c1 and 50c2 of FIG. 2A).

The second lower contact layer 317c includes a region overlapping the LED 30, and may additionally extend to the outside of the LED 30. The second lower contact layer 317c may be formed of a light-transmitting material such as a metallic material or a conductive oxide layer. In particular, the second lower contact layer 317c may be formed of a material that is transparent to light emitted from the LEDs 30 and 40.

### Third Floor)

The third floor may be attached to the second floor by the upper adhesive layer 340. The LEDs 40 may be arranged on the upper adhesive layer 430. The third lower contact layer 417c is disposed between the upper adhesive layer 340 and the LEDs 40. The LEDs 40 are disposed so as to at least partially overlap the LEDs 30, respectively.

The first conductivity type semiconductor layer 43 of the LED 40 may include a first surface facing the active layer 45 and a second surface opposite to the first surface, and a growth substrate is removed to expose the first conductivity type semiconductor layer 43.

The third lower contact layer 417c is disposed on the exposed second surface of the first conductivity type semiconductor layer 43, and the third upper contact layer 419c is disposed on the second conductivity type semiconductor layer 47. The third lower contact layer 417c and the third upper contact 419c may be electrically connected to the first and second conductivity type semiconductor layers 43 and 47, respectively.

The third lower contact layer 417c may extend to the outside of the LED 40, and electrically connected to the pixel device pad 50c1 through the via 50v. The third lower contact layer 417c may electrically connect adjacent LEDs 40, and furthermore, a plurality of third lower contact layers 417c may be disposed. The third lower contact layers 417c may be electrically connected to different pixel device pads (e.g., 50c1 and 50c2 of FIG. 2A).

The third lower contact layer 417c includes a region overlapping the LED 40, and may additionally extend to the outside of the LED 40. The third lower contact layer 417c may be formed of a light-transmitting material such as a metallic material or a conductive oxide layer. In particular, the third lower contact layer 417c may be formed of a material that is transparent to light emitted from the LEDs 40.

In this embodiment, the first through third lower contact layers 217c, 317c, and 417c may be directly connected to the via 50v, but the inventive concepts are not limited thereto. For example, as described with reference to FIGS. 2A through 2C, the first through third lower pads may be formed on the insulation layers 215, 315, and 415, respectively, may be electrically connected to the first through third lower contact layers 217c, 317c, and 417c, respectively, and the via 50v may be electrically connected through the first to third lower contact pads. Accordingly, the first through third lower pads may be formed of a material having a light transmittance different from those of the first through third lower contact layers 217c, 317c, and 417c.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

1. A pixel device, comprising:
a first floor including a first LED, and a first lower pad and a first upper pad electrically connected to the first LED;
a second floor disposed over the first floor, and including a second LED, and a second lower pad and a second upper pad electrically connected to the second LED; and
a third floor disposed over the second floor, and including a third LED, and a third lower pad and a third upper pad electrically connected to the third LED.

2. The pixel device of claim 1,
wherein the first LED, the second LED, and the third LED emit visible light of different colors from one another.

3. The pixel device of claim 1, wherein:
the first through third lower pads are electrically connected to one another, and
the first through third upper pads are electrically spaced apart from one another.

4. The pixel device of claim 1, further comprising:
a lower adhesive layer bonding the first floor and the second floor; and
an upper adhesive layer bonding the second floor and the third floor.

5. The pixel device of claim 1,
wherein the first through third LEDs are disposed so as to overlap one another in a vertical direction.

6. The pixel device of claim 5,
wherein he first through third LEDs partially overlap one another.

7. The pixel device of claim 1, further comprising:
a light blocking layer surrounding the first LED, the second LED, or the third LED.

8. The pixel device of claim 1, further comprising:
a first insulation layer covering the first LEDs and a first planarization layer covering the insulation layer,
wherein the first upper pad is disposed on the first planarization layer.

9. The pixel device of claim 8,
wherein the first lower pad is disposed between the first insulation layer and the first planarization layer or on the first planarization layer.

10. The pixel device of claim 1, wherein:
the second floor further includes a second insulation layer covering the second LEDs and a second planarization layer covering the second insulation layer, and
the second upper pad is disposed on the second planarization layer.

11. The pixel device of claim 10,
wherein the second lower pad is disposed between the second insulation layer and the second planarization layer or on the second planarization layer.

12. The pixel device of claim 1, wherein:
the third floor further includes a third insulation layer covering the third LEDs and a third planarization layer covering the third insulation layer, and
the third upper pad is disposed on the third planarization layer.

13. The pixel device of claim 12,
wherein the third lower pad is disposed between the third insulation layer and the third planarization layer or on the third planarization layer.

14. The pixel device of claim 1, further comprising:
an upper insulation layer covering the third floor; and
pixel device pads disposed on the upper insulation layer,
wherein the pixel device pads are electrically connected to at least one of the first through third lower pads and the first through third upper pads, respectively.

15. The pixel device of claim 14, wherein:
a plurality of first LEDs, a plurality of second LEDs, and a plurality of third LEDs are arranged in a matrix of n×m (n, m is a positive integer) on the first through third floors, respectively, and
the number of pixel pad electrodes is (3 n+m).

16. The pixel device of claim 14, wherein:
the pixel device pads are electrically connected to at least one of the first through third lower pads and the first through third upper pads through connection vias, and
the connection vias are spaced apart from the first through third LEDs in a lateral direction.

17. The pixel device of claim 1, wherein:
the first through third lower pads are electrically connected to cathodes of the first through third LEDs, respectively, and
the first through third upper pads are electrically connected to anodes of the first through third LEDs, respectively.

18. A display apparatus, comprising:
a circuit board; and
a pixel device disposed on the circuit board,
the pixel device, comprising:
a first floor including a first LED, and a first lower pad and a first upper pad electrically connected to the first LED;
a second floor disposed over the first floor, and including a second LED, and a second lower pad and a second upper pad electrically connected to the second LED; and
a third floor disposed over the second floor, and including a third LED, and a third lower pad and a third upper pad electrically connected to the third LED.

19. The display apparatus of claim 18,
the pixel device, further comprising:
an upper insulation layer disposed on the third floor and pixel device pads disposed on the upper insulation layer,
wherein the pixel device pads are bonded to the circuit board.

20. The display apparatus of claim 19, wherein:
the pixel device pads are electrically connected to at least one of the first through third lower pads and the first through third upper pads through connection vias, and
the connection vias are spaced apart from the first through third LEDs in a lateral direction.
